(19) United States
(12) Patent Application Publication
(10) Pub. No.: US 2026/0358395 A1
(43) Pub. Date: Nov. 12, 2026

(54) METHODS, SYSTEMS, AND COMPUTER READABLE MEDIA FOR MULTIPATH-ENHANCED MEASUREMENT OF ANTENNA RADIATION PATTERNS

(71) Applicant: North Carolina State University, Raleigh, NC (US)

(72) Inventor: Daniel Dean Stancil, Raleigh, NC (US)

(21) Appl. No.: 19/701,683

(22) Filed: Jun. 8, 2026

Related U.S. Application Data
(60) Provisional application No. 63/820,679, filed on Jun. 9, 2025.

(51) Int. Cl. G01R 29/10; G01R 29/08

(52) U.S. Cl. CPC G01R 29/105; G01R 29/0892

(57) ABSTRACT

A method for multipath-enhanced measurement of antenna radiation patterns includes determining relationships between reference signals measured or generated by sensing antennas in a multipath environment and functions defined on a surface of a sphere. The method further includes applying a signal to the antenna under test located in the multipath environment. The method further includes detecting, by each of a plurality of sensing antennas, signals radiated by the antenna under test, including multipath reflections of the radiated energy in the multipath environment. The method further includes determining, using the detected signals and the relationships between the reference signals and the functions defined on the surface of the sphere, a radiation pattern of the antenna under test.

### CROSS-REFERENCE TO RELATED APPLICATIONS

This application claims the priority benefit of U.S. Provisional Patent Application Ser. No. 63/820,679, filed Jun. 9, 2025, the disclosure of which is incorporated herein by reference in its entirety.

### TECHNICAL FIELD

The subject matter described herein relates to measuring antenna radiation patterns. More particularly, the subject matter described herein relates to methods, systems, and computer readable media for multipath enhanced measurement of antenna radiation patterns.

### BACKGROUND

It is often desirable to measure the electromagnetic radiation pattern of an antenna prior to placing the antenna into service. One reason for measuring the antenna radiation pattern is to evaluate the effectiveness of the antenna. Another reason may be for electromagnetic compatibility (EMC) testing to ensure that the antenna will comply with regulatory requirements for antenna radiation.

One traditional approach for measuring the radiation pattern of an antenna is to place the antenna in an anechoic chamber to minimize multipath radiation caused by reflections of the signal radiated by the antenna. The anechoic chamber isolates the antenna from external radiation sources. In addition, the surfaces in the anechoic chamber (e.g., the walls and ceiling) contain radiation-absorbing structures, such as cones made of a radio-frequency (RF)-absorptive material, to minimize reflections.

While measuring an antenna radiation pattern in an anechoic chamber is effective, anechoic chambers are expensive to construct, and, as a result, are not universally available. Accordingly, in light of this and other difficulties, there exists a need for improved methods, systems, and computer readable media for measuring antenna radiation patterns.

### SUMMARY

A method for multipath-enhanced measurement of antenna radiation patterns includes determining relationships between reference signals measured or generated by sensing antennas in a multipath environment and functions defined on a surface of a sphere. The method further includes applying a signal to the antenna under test located in the multipath environment. The method further includes detecting, by each of a plurality of sensing antennas, signals radiated by the antenna under test, including multipath reflections of the radiated energy in the multipath environment. The method further includes determining, using the detected signals and the relationships between the reference signals and the functions defined on the surface of the sphere, a radiation pattern of the antenna under test.

The subject matter described herein can be implemented in software in combination with hardware and/or firmware. For example, the subject matter described herein can be implemented in software executed by a processor. In one exemplary implementation, the subject matter described herein can be implemented using a non-transitory computer readable medium having stored thereon computer executable instructions that when executed by the processor of a computer control the computer to perform steps. Exemplary computer readable media suitable for implementing the subject matter described herein include non-transitory computer-readable media, such as disk memory devices, chip memory devices, programmable logic devices, and application specific integrated circuits. In addition, a computer readable medium that implements the subject matter described herein may be located on a single device or computing platform or may be distributed across multiple devices or computing platforms.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

Exemplary implementations of the subject matter described herein will now be made with reference to the accompanying drawings, of which:

FIG. 1A is a schematic diagram of an antenna radiation pattern measurement system. The antenna to be tested is placed in a multipath environment. Multiple probes are placed in the environment to sample the excited fields. An N:1 coaxial switch enables the 2-port vector network analyzer to measure the amplitude and phase of the signal coupled from each probe;

FIG. 1B is a schematic diagram illustrating the measurement system in FIG. 1A in more detail. The diagram in FIG. 1B illustrates the presence of reflectors that cause the multipath reception of a transmitted signal;

FIG. 2 illustrates a geometry for a center-fed, symmetric electric dipole antenna. The dipole is centered at the origin with its axis along the direction (θ₀, φ₀), and the observation is made at a distance r in the direction (θ, φ);

FIG. 3 illustrates examples of spherical harmonic decomposition of half-wave dipoles with various orientations. The coefficients for ±m have the same magnitudes but different phases (phases not shown). Orientations from top to bottom: (θ, φ)=(0,0), (π/2, 0), (π/2, π/2), (π/4, π/4). Coefficient magnitudes are normalized to the top case (0,0);

FIGS. 4A and 4B illustrate properties of a set of electric dipole calibration antennas;

FIG. 5 illustrates an example reconstruction of a simulated antenna radiation pattern in a random multipath environment;

FIG. 6 illustrates a summary of the errors in directivity and radiation resistance over the full range of test antenna orientations. The white circles indicate the positive axis of the calibration dipoles, and the crosses denote the negative axes (diametrically opposite to the positive axes). Note that the RMS field error is smallest near the reference antenna orientations, as expected;

FIG. 7 is a block diagram illustrating an exemplary system for multipath enhanced measurement of antenna radiation patterns;

FIG. 8 is a flow chart illustrating an exemplary process for multipath-enhanced measurement of antenna radiation patterns;

FIG. 9A is a block diagram of a multipath antenna radiation pattern measurement system;

FIG. 9B is a photograph of an experimental multiplexing system. The interchange of connections to patches 1 and 2 was required owing to the use of a 1:2 switch with reversed outputs;

FIG. 10A is a photograph of a sleeve dipole mounted on a custom goniometer;

FIG. 10B is a closeup view of the sleeve dipole used in the multipath antenna radiation pattern measurement experiments;

FIG. 11A is a photograph of the test setup in a garage. The 10 patch antennas used for sensing are mounted with different heights and orientations on the wooden posts. The test dipole and goniometer are mounted on a camera tripod at the center. The Fieldfox vector network analyzer can be seen on the small table, and the Raspberry Pi, RF switching circuits and ethernet switch are on the floor beneath the tripod. The experiment was initiated from a laptop located outside of the garage and connected to the Raspberry Pi via ethernet. This ensured there was no movement in the environment while the measurements were made;

FIG. 11B is a plan view of approximate layout of the AUT (labeled “A”) and the 10 patch antennas. The approximate heights of the antennas above the floor are given in Table I. The dashed box represents the orientation of the walls of the garage with respect to the test setup, and is not shown to scale for clarity. The shaded circles represent the patch antennas that maximized the 1-entropy for the Matrix Inversion method;

FIG. 12A is a photograph of the test setup in a university laboratory;

FIG. 12B is schematic diagram of the test setup in the university laboratory with metal scatterers labeled. The room boundary is not illustrated;

FIG. 13A is a photo of the test setup in an anechoic chamber with no additional reflectors;

FIG. 13B is a photograph illustrating reflectors above and to the sides of the antenna under test;

FIG. 13C is a plan view of the test setup in the anechoic chamber. Reflectors are not illustrated;

FIG. 14 is a graph of RMS error in weights W versus the 1-entropy H₁, FIG. 15 is a graph illustrating a comparison between the condition of the channel matrix versus its 1-entropy H₁;

FIG. 16A illustrates graphs of measured antenna radiation patterns in the garage from an antenna under test with the largest error (orientation 10);

FIG. 16B illustrates graphs of measured antenna radiation patterns in the garage from an antenna under test with the smallest error (orientation 2). In both FIGS. 16A and 16B, the left-most pattern is the theoretical pattern for the known orientation;

FIG. 17A illustrates graphs of measured antenna radiation patterns in the university laboratory from an antenna under test with the largest error (orientation 9);

FIG. 17B illustrates graphs of measured antenna radiation patterns in the university laboratory from an antenna under test with the smallest error (orientation 1). In both FIGS. 17A and 17B, the left-most pattern is the theoretical pattern for the known orientation;

FIG. 18A illustrates graphs of measured antenna radiation patterns in the anechoic chamber without reflectors from an antenna under test with the largest error (orientation 10);

FIG. 18B illustrates graphs of measured antenna radiation patterns in the anechoic chamber without reflectors from an antenna under test with the smallest error (orientation 4). In both FIGS. 18A and 18B, the left-most pattern is the theoretical pattern for the known orientation;

FIG. 19A illustrates graphs of measured antenna radiation patterns in the anechoic chamber with reflectors from an antenna under test with the largest error (orientation 2);

FIG. 19B illustrates graphs of measured antenna radiation patterns in the anechoic chamber with reflectors from an antenna under test with the smallest error (orientation 1). In both FIGS. 19A and 19B, the left-most pattern is the theoretical pattern for the known orientation;

FIG. 20 is a diagram illustrating the geometry of a waveguide for implementing the multipath-enhanced antenna pattern measurement technique. The calibration and test antennas are dipoles with variable orientation;

FIG. 21 is an illustration of probe locations listed in Table IX;

FIG. 22A illustrates graphs of measured antenna radiation patterns in the waveguide from an antenna under test with the largest error (orientation 6); and

FIG. 22B illustrates graphs of measured antenna radiation patterns in the waveguide from an antenna under test with the smallest error (orientation 4). In both FIGS. 22A and 22B, the left-most pattern is the theoretical pattern for the known orientation.

### DETAILED DESCRIPTION

### Multi-Path Enhanced Measurement of Antenna Patters: Theory

### I. INTRODUCTION

As described above, one traditional method of measuring antenna radiation patterns requires an anechoic environment so that there is a single known direction for test signals to be either sent or received. Consequently, multipath propagation was considered to be a source of errors, and techniques were developed to minimize its effects. Approaches explored include using the matrix pencil method to fit a sum of complex exponentials to the signal [1]-[4], time gating to keep only the direct path signal [3], [5]-[9], and various compensation and equalization techniques [10]-[12]. However, anechoic chambers are expensive to construct, and a large number of pattern samples are often required to adequately characterize the three-dimensional patterns. One way to reduce the cost of the facility is to use reverberation chambers. Reverberation chamber approaches include averaging out multipath using stirrers [13]-[18], estimation of the Ricean K factor [19]-[21], and using the Doppler spectrum obtained by moving the antenna under test [22], [23].

In a somewhat analogous manner, multipath propagation in communication systems was traditionally considered an impairment that must be mitigated by, for example, equalization or diversity combining. In contrast, following the work of Foschini and Gans [24], Telatar [25] and others, it was shown that if multiple transmit and receive antennas are used, multipath can be exploited to increase the information capacity of the system by creating multiple simultaneous channels.

As described herein, a similar point of view is applied to antenna radiation pattern measurements in non-anechoic environments. In particular, it is shown that the use of multiple measurement antennas can effectively realize multiple simultaneous channels, each of which conveys independent information about the antenna pattern.

To minimize the number of measurement antennas required, we need an efficient mathematical representation of the antenna radiation pattern. A particularly compact way to represent 3D antenna patterns is with spherical harmonics [26]-[41]. This work builds on these two ideas, using multipath to extract pattern information, and using spherical harmonics to minimize the number of sense antennas needed by efficiently representing the pattern information.

### II. SYSTEM CONFIGURATION

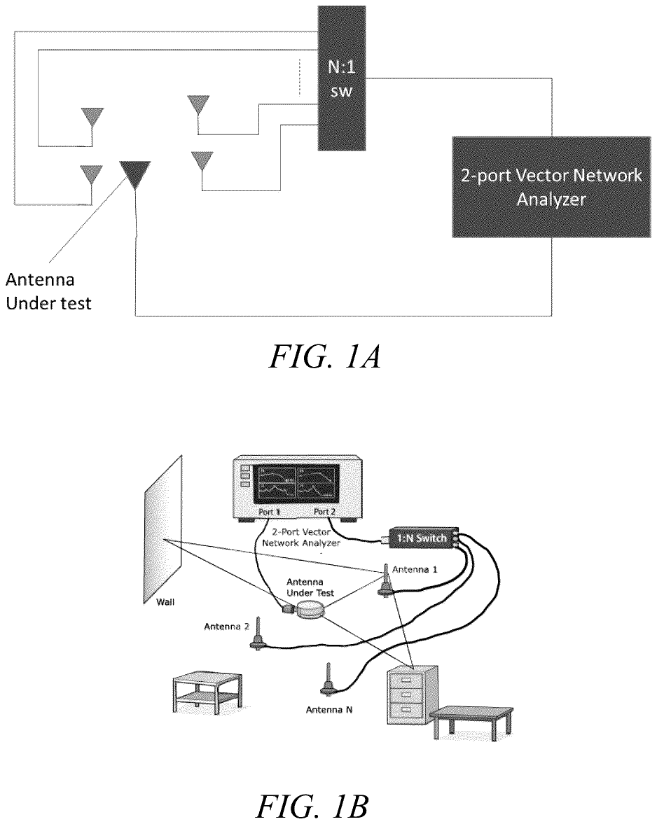

A block diagram of the proposed system is shown in FIG. 1. The antenna under test is placed in a multipath environment. It is assumed that the scattering objects are sufficiently far from the antenna under test (AUT) that the presence of the sources of reflection do not significantly affect the behavior of the AUT. Example environments include an ordinary room, a large multimode waveguide, or reverberation chamber. The voltages induced at multiple probes placed in or around the surfaces of the chamber are then measured. The radiation properties are then obtained by analyzing the set of measured voltages. The analysis approach is described in the following sections.

The antenna pattern can be decomposed into a series of spherical harmonics, and each spherical harmonic pattern excites waves bouncing around in the environment in a unique way. By finding the mapping between spherical harmonics and the voltages measured at the probes, the complex amplitudes of each spherical harmonic in the series can be determined. The radiation properties of the antenna in free space can then be calculated based on the spherical harmonic decomposition. In the following sections these ideas are put on a more concrete mathematical basis.

### III. SPHERICAL HARMONIC EXPANSIONS

Electromagnetic fields in a source-free region can be expanded in terms of vector spherical harmonics (VSH) [26]-[28], [42] as well as scalar spherical harmonics (SSH) with vector coefficients [32], [35]. Scalar spherical harmonics with vector coefficients have the advantage of avoiding singularities in the antenna field on the poles [32], whereas Mhedhbi et al [35] found that vector spherical harmonics gave a more efficient representation in terms of the number of harmonic coefficients needed. Since we are interested particularly in efficient pattern representations, we proceed with the vector spherical harmonic formulation.

For outgoing waves and assuming the time dependence exp (jωt) we have

$$E = {\sum }_{l , m} [ {a}_{l , m}^{M} {h}_{l}^{( 2 )} ( kr ) {X}_{l , m} - \frac{j}{{ωϵ}_{0}} {a}_{l , m}^{E} ∇ \times ( {h}_{l , m}^{( 2 )} ( kr ) {X}_{l , m} ) ] , \qquad ( 1 )$$

$$H = \frac{j}{ω {μ}_{0}} ∇ \times E . \qquad ( 2 )$$

Here the vector spherical harmonics are defined by

$${X}_{l , m} = - \frac{j}{\sqrt{l ( l + 1 )}} r \times ∇ {Y}_{l , m} ( θ , ϕ ) , \qquad ( 3 )$$

and

$${h}_{l}^{( 2 )} ( x )$$

the spherical Hankel function

$${h}_{l}^{( 2 )} ( x ) = {j}_{l} ( x ) - {jn}_{l} ( x ) \qquad ( 4 )$$

$$= \sqrt{\frac{π}{2 x}} [ {J}_{l + \frac{1}{2}} ( x ) - {jN}_{l + \frac{1}{2}} ( x ) ] \qquad ( 5 )$$

In the above, Yum is the spherical harmonic defined as

$${Y}_{l , m} ( θ , ϕ ) ≡ {Y}_{l , m} ( Ω ) = \sqrt{\frac{( 2 l + 1 ) ( l - m ) !}{4 π ( l + m ) !}} {P}_{l}^{m} ( cos θ ) {e}^{jm ϕ} , \qquad ( 6 )$$

$$l = 0 , 1 , 2 , 3 …$$

$$m = - l , - l + 1 … + l$$

$${P}_{l}^{m} ( x )$$

is the Associate Legendre function

$${P}_{l}^{m} ( x ) = {( - 1 )}^{m} {( 1 - {x}^{2} )}^{\frac{m}{2}} \frac{{d}^{m}}{{dx}^{m}} {P}_{l} ( x ) , \qquad ( 7 )$$

Pₗ(x) is the Legendre function

$${P}_{l} ( x ) = \frac{1}{{2}^{l} l !} \frac{{d}^{l}}{{dx}^{l}} {( {x}^{2} - 1 )}^{l} , \qquad ( 8 )$$

jₗ(x), nₗ(x) are the spherical Bessel and Neumann functions, respectively, and J_{l+1/2} (x), N_{l+1/2}(x) are the regular Bessel and Neumann functions of half-integer order. Explicit expressions for the vector spherical harmonics are given in the section below entitled, “Expressions for Vector Spherical Harmonics”.

The vector spherical harmonics have the following properties:

$$\int {X}_{{l}^{′} , {m}^{′}}^{*} \cdot {X}_{l , m} d Ω = {δ}_{l , {l}^{′}} {δ}_{m , {m}^{′}} \qquad ( 9 )$$

$$\int {X}_{{l}^{′} , {m}^{′}}^{*} \cdot \hat{r} \times {X}_{l , m} d Ω = 0 , \qquad ( 10 )$$

$$\begin{matrix}\hat{r} \cdot {X}_{l , m} = & ( 11 )\end{matrix}$$

Further, it follows from (9) and (11) that¹ ¹ Since \hat{r} is perpendicular to X_{l,m}, from (11), \hat{r}×x_{l,m} has a different direction but the same amplitude as X_{l,m}. Consequently

$$( \hat{r} \times {X}_{l , m} ) \cdot ( \hat{r} \times {X}_{l , m} ) = {X}_{{l}^{′} , {m}^{′}}^{*} \cdot {X}_{l , m}$$

and (12) follows.

$$\int ( \hat{r} \times {X}_{{l}^{′} , {m}^{′}}^{*} ) \cdot ( \hat{r} \times {X}_{l , m} ) d Ω = {δ}_{l , {l}^{′}} {δ}_{m , {m}^{′}} . \qquad ( 12 )$$

In the far-field, the large-argument expansion can be used for the spherical

$${h}_{l}^{( 2 )} ( kr ) :$$

$${h}_{l}^{( 2 )} ( kr ) \approx {j}^{l + 1} \frac{{e}^{- jkr}}{kr} kr >> 1. \qquad ( 13 )$$

It follows that the far-field approximations to the electromagnetic fields are

$$E = \frac{{e}^{- jkr}}{kr} {\sum }_{l , m} {j}^{l + 1} [ {a}_{l , m}^{M} {X}_{l , m} - {η}_{0} {a}_{l , m}^{E} \hat{r} \times {X}_{l , m} ] , \qquad ( 14 )$$

$$H = \frac{1}{{η}_{0}} \hat{r} \times E . \qquad ( 15 )$$

Here η₀=\sqrt{μ₀∈₀} is the impedance of free space.

Alternatively, the coefficients can be extracted from a measured field E using

$${a}_{l , m}^{M} = {( - j )}^{l + 1} kr {e}^{jkr} \int E \cdot {X}_{l , m}^{*} d Ω , \qquad ( 16 )$$

$${a}_{l , m}^{E} = - \frac{{( - j )}^{l + 1}}{{η}_{0}} kr {e}^{jkr} \int E \cdot ( \hat{r} \times {X}_{l , m}^{*} ) d Ω . \qquad ( 17 )$$

The coefficients for both electric and magnetic dipole components have the property

$${a}_{l , - m} = {( - 1 )}^{m} {a}_{l , m}^{*} . \qquad ( 18 )$$

The complex Poynting vector is given by

$$S = \frac{1}{2} E \times H *= \frac{1}{2 {η}_{0}} E \times ( \hat{r} \times E \text{*)} = \frac{1}{2 {η}_{0}} {\vert E \vert}^{2} \hat{r} . \qquad ( 19 )$$

The last step follows since E·\hat{r}=0 in the far-field. The magnitude squared of the electric field can be written

$${\vert E \vert}^{2} = \frac{1}{{( kr )}^{2}} {\sum }_{{l}^{′} , {m}^{′}} {j}^{{l}^{′} + 1} {\sum }_{l , m} {{( - j )}^{l + 1} [ {a}_{{l}^{′} , {m}^{′}}^{M} {X}_{{l}^{′} , {m}^{′}} - {η}_{0} {a}_{{l}^{′} , {m}^{′}}^{E} \hat{r} \times {X}_{{l}^{′} , {m}^{′}} ]}^{*} \cdot [ {a}_{l , m}^{M} {X}_{l , m} - {η}_{0} {a}_{l , m}^{E} \hat{r} \times {X}_{l , m} ] = \frac{1}{{( kr )}^{2}} {\sum }_{{l}^{′} , {m}^{′}} {j}^{{l}^{′} + 1} {\sum }_{l , m} {( - j )}^{l + 1} \cdot [ {( {a}_{{l}^{′} , {m}^{′}}^{M} )}^{*} {a}_{l , m}^{M} {X}_{{l}^{′} , {m}^{′}}^{*} \cdot {X}_{l , m} + {{η}_{0}^{2} ( {a}_{{l}^{′} , {m}^{′}}^{E} )}^{*} {a}_{l , m}^{E} ( \hat{r} \times {X}_{{l}^{′} , {m}^{′}}^{*} ) \cdot ( \hat{r} \times {X}_{l , m} ) - {η}_{0} ( {( {a}_{{l}^{′} , {m}^{′}}^{M} )}^{*} {a}_{l , m}^{E} {X}_{{l}^{′} , {m}^{′}}^{*} \cdot \hat{r} \times {X}_{l , m} + c . c ) ] \qquad ( 20 )$$

To find the total power radiated, we substitute this into (19) and integrate over the surface of a sphere at the far-field radius r. The last two terms in (20) vanish owing to the orthogonality relation (10), and the first two terms simplify using the orthonormal relations (9) and (12). The result is

$$P = \frac{1}{2 {η}_{0} {k}^{2}} {\sum }_{l , m} [ {\vert {a}_{l , m}^{M} \vert}^{2} + {η}_{0}^{2} {\vert {a}_{l , m}^{E} \vert}^{2} ] . \qquad ( 21 )$$

The radiation resistance of the antenna is then given by

$${R}_{r} = \frac{2 P}{{\vert I \vert}^{2}} , \qquad ( 22 )$$

where I is the current input to the antenna terminals.

For antennas with high efficiency, the radiation resistance and the antenna impedance (assuming no reactive part) will be very nearly equal. In this case the antenna impedance is more readily measured with a vector network analyzer connected to the antenna terminals (to measure S₁₁). Eq. (22) can then be compared with the impedance obtained from the network analyzer as a check to ensure that the spherical harmonic expansion is correct. For low efficiency antennas, the efficiency of the antenna can be estimated by comparing the radiation resistance (22) to the antenna terminal impedance.

Finally, the directivity can be obtained from

$$D = \frac{4 π {r}^{2}}{P} \frac{max {\vert E \vert}^{2}}{2 {η}_{0}} . \qquad ( 23 )$$

For calculations, it is convenient to introduce a “modified field” and “modified electric multipole coefficient” defined as

$$\tilde{E} = kr {e}^{j k r} E , \qquad ( 24 )$$

$${ã}_{l , m}^{E} = - {η}_{0} {a}_{l , m}^{E} . \qquad ( 25 )$$

In terms of these quantities we have

$$\tilde{E} = {\sum }_{l , m} {j}^{l + 1} [ {a}_{l , m}^{M} {X}_{l , m} + {ã}_{l , m}^{E} \hat{r} \times {X}_{l , m} ] , \qquad ( 26 )$$

$${a}_{l , m}^{M} = {( - j )}^{l + 1} \int \tilde{E} \cdot {X}_{l , m}^{*} d Ω , \qquad ( 27 )$$

$${ã}_{l , m}^{E} = {( - j )}^{l + 1} \int \tilde{E} \cdot ( \hat{r} \times {X}_{l , m}^{*} ) d Ω , \qquad ( 28 )$$

$$P = \frac{1}{2 {η}_{0} {k}^{2}} {\sum }_{l , m} [ {\vert {a}_{l , m}^{M} \vert}^{2} + {\vert {ã}_{l , m}^{E} \vert}^{2} ] , \qquad ( 29 )$$

$$D = \frac{4 πmax {\vert \tilde{E} \vert}^{2}}{2 {η}_{0} {k}^{2} P} . \qquad ( 30 )$$

To summarize, if we know the coefficients of the vector spherical harmonics of the radiated field

$${a}_{l , m}^{E} , {a}_{l , m}^{M}$$

for a given I, then we can calculate the radiation pattern, directivity, and radiation resistance of the antenna.

### IV. ANTENNA IN A MULTIPATH ENVIRONMENT

Suppose that an antenna to be tested is placed in a multipath environment. If there are Nₛ sensing antennas and Nₚ significant paths, then the voltages induced at the mth antenna can be written

$${v}_{m} = {\sum }_{n = 1}^{{N}_{p}} {Q}_{m n} {c}_{n} , \qquad ( 31 )$$

$$v = Q \cdot c .$$

Here Q is a Nₛ×Nₚ coupling matrix between the sensing antennas and the multiple paths, and c is a Nₚ×1 matrix (column vector) containing the amplitudes of the paths.

Now suppose that the antenna under test is band-limited in spherical harmonics; i.e., there is a finite number N_{Λ} of vector spherical harmonics with non-negligible amplitudes. Here, the band-limited assumption is imposed by assuming that all coefficients have negligible amplitudes for l>Λ. For each value of l there are 2l+1 spherical harmonics. This observation applies to both

$${a}_{l , m}^{E} , {a}_{l , m}^{M} ,$$

so the limit on the total number of harmonics for the band-limited system is therefore

$${N}_{Λ} = 2 {\sum }_{l = 1}^{Λ} ( 2 l + 1 ) = 2 Λ ( Λ + 2 ) . \qquad ( 32 )$$

Note that we have started the sum with l=1 since for antenna problems, the spherically symmetric function for l=0 will not occur.

Each one of these spherical harmonic components will excite a unique distribution of paths, so we can write

c=D·a, (33)
where

$$a = [ \begin{matrix}{a}^{E} \\ {a}^{M}\end{matrix} ] , {a}^{E} = [ \begin{matrix}{a}_{1 , - 1}^{E} \\ {a}_{1 , 0}^{E} \\ ⋮ \\ {a}_{Λ , Λ}^{E}\end{matrix} ] , {a}^{M} = [ \begin{matrix}{a}_{1 , - 1}^{M} \\ {a}_{1 , 0}^{M} \\ ⋮ \\ {a}_{Λ , Λ}^{M}\end{matrix} ] . \qquad ( 34 )$$

Here D is an Nₚ×N_{Λ} matrix describing the coupling between vector spherical harmonics and propagation paths, and a is an N_{Λ}×1 matrix (column vector) of vector spherical harmonic amplitudes associated with the antenna under test. The connection between the vector spherical harmonic amplitudes and the measured probe voltages can therefore be written

v=Q·D·a. (35)

If Q·D is invertible, then the spherical harmonic amplitudes can be recovered from the voltage measurements using

a=[Q·D]⁻¹·v. (36)

Note that to preserve information, both the number of paths and the number of sensing antenna measurements must be at least as large as the number of non-negligible vector spherical harmonics; i.e., Nₚ≥N_{Λ}, Nₛ≥N_{Λ}.

### V. CALIBRATION OF THE ENVIRONMENT

The matrices Q, D could be computed from first principles using the geometry of the environment, the equivalent antenna currents, and the probe geometry, but experimentally it may be preferable to calibrate the system from a series of reference antennas. (The first-principles calculation would likely need to be numerical in general, depending on the complexity of the environment.) A reference antenna in this context would be one for which the complete pattern has been measured or computed and decomposed into its vector spherical harmonic components.

Given N_{R} reference antennas, we can construct the N_{Λ}×N_{R} matrix whose columns are the spherical harmonic coefficient vectors for each reference antenna:

A_{R}=[a₁ a₂ . . . a_{N}_{_{R}}] (37)

If we measure the sensing antenna voltages for each of these reference antennas we can also construct the Nₛ×N_{R} voltage matrix V such that

V_{R}=[v₁ v₂ . . . v_{N}_{_{R}}]. (38)

It follows that

V_{R}=Q·D·A_{R}. (39)

If the matrix A_{R} is invertible, then the matrix Q·D can be obtained from

$$Q \cdot D = {V}_{R} \cdot {A}_{R}^{- 1} , \qquad ( 40 )$$

$$and$$

$${[ Q \cdot D ]}^{- 1} = {A}_{R} \cdot {V}_{R}^{- 1} . \qquad ( 41 )$$

It is also possible to separate the analysis into two steps as follows. Let

$${v}_{j}^{TA}$$

be the measured voltage at the jth sensing antenna owing to the antenna under test. An estimate

$${v}_{j}^{e} of {v}_{j}^{TA}$$

can be constructed with a weighted sum of the voltages from the reference antennas:

v^{e}=V_{R}·w. (42)

In this case the weights can be obtained directly from

$$w = {V}_{R}^{- 1} \cdot {v}^{e} . \qquad ( 43 )$$

Owing to the linearity of the system, an estimate of the vector containing the spherical harmonic amplitudes of the test antenna would then be

a^{e}=A_{R}·w. (44)

If we require that all antennas are mounted so that their phase centers are coincident, then the coefficients wᵢ should be real.

### VI. LEAST-SQUARE-ERROR METHOD

The calculations in the previous section require key matrices to be invertible, namely square and non-singular. While squareness can be achieved by choosing Nₛ=N_{Λ}, singular or ill-conditioned matrices will occur if the amplitudes of some spherical harmonics are zero or close to zero. Since we assume we do not know the amplitudes a priori, we need an approach that avoids the need to invert ill-conditioned matrices. The least-square-error (LSE) method should be robust independent of the spherical harmonic content, so we proceed with this approach [35].

The formulation of the LSE method is as follows. We would like to find the weights wᵢ that minimize the error function

ε=(v^{TA}−v^{e})^{†}·(v^{TA}−v^{e}). (45)

Setting the derivatives with respect to wᵢ to zero gives a set of simultaneous equations that can be written in matrix form and solved for the coefficients wᵢ:

$$w = {[ Re \{ {V}_{R}^{†} \cdot {V}_{R} \} ]}^{- 1} \cdot Re \{ {V}_{R}^{†} \cdot {v}^{T A} \} , \qquad ( 46 )$$

where w is the vector of coefficients wᵢ.

It may be possible to improve the accuracy by imposing a normalization condition as a constraint on the minimization of (45). Such a normalization is equivalent to holding the total power constant. A straightforward choice is simply

w^{T}·w=1. (47)

If the efficiency of the test antenna is known, another choice of normalization is the radiation resistance constraint (22)

$$\frac{2 P}{\vert I {\vert}^{2}} = {R}_{Meas} - {R}_{loss} , \qquad ( 48 )$$

where R_{Meas} is the actual measured terminal resistance, and Rₗₒₛₛ represents the loss of the antenna in the form of a resistance in series with the radiation resistance. (We assume reactive components have been tuned out.)

### VII. CHOICE OF MODEL PARAMETERS

### A. Estimating the Number of Modes

For a given spherical harmonic with index l, the mode decays rapidly with increasing r if kr<l, and decays as 1/r for kr>l. Consequently, the mode is evanescent for kr<l, and propagating for kr>l. It follows that if the smallest sphere that encloses the antenna has the radius R, then the contributions from spherical harmonics with l>kR rapidly decrease with increasing l.

Thus an estimate for the limit on A is given by

$$Λ \leq ⌈ kR ⌉ = ⌈ \frac{2 πR}{λ} ⌉ \qquad ( 49 )$$

where ┌ ℏ represents the ceiling function.

Jensen and Frandsen [44] have studied the amount of relative power excluded by truncating the spherical harmonic series, and found that for an infinitesimal dipole located at R such that kR=30, truncation at Λ=kR results in excluding relative power of about −15 dB. Based on additional calculations for larger values of kR, they gave a more conservative estimate based on the desired level of accuracy:

$$Λ = k R + 0.045 \sqrt[3]{k R} ( {P}_{R} - {P}_{t r} ) , \qquad ( 50 )$$

where P_{R} is the power in dB of the source at r=R relative to the total power, and Pₜᵣ is the power excluded by the truncation, relative to P_{R} (dB). Taking P_{R}=0 dB gives

$$Λ = k R - 0.045 \sqrt[3]{k R} {P}_{t r} . \qquad ( 51 )$$

This expression is valid for kR>>1 and Pₜᵣ≤−40 dB. For example, for Pₜᵣ=−40 dB, we have

$$Λ = k R + 1.8 \sqrt[3]{k R} . \qquad ( 52 )$$

Once an estimate for Λ is obtained, the resulting number of spherical harmonics is given by (32). This assumes that the antenna could have both electric and magnetic multipole sources. If it is known, for example, that the antenna only has electric or magnetic multipole sources, (e.g., a loop antenna or an electric dipole), then the number of coefficients is reduced by half.

For small antennas where kR<<30, it may be necessary to begin with one of these estimates, then change the number of VSH amplitudes included until the results satisfy the required accuracy.

In addition to the reduction of complexity realized by estimating the band-limited properties of the pattern, it may often be the case that many spherical harmonic coefficients have negligible amplitudes even within the band-limited range. Thus, even within the band-limited constraint, the coefficient vector may be sparse. In this case, it is likely that compressed sensing techniques [45] can be used to minimize the number of measurements needed to obtain accurate reconstruction of the function.

### B. Choice of Sensor Antenna Locations

If the matrix inversion method is used, then a key requirement is for the matrix to be inverted, Q·D, to be well conditioned. Consequently, the locations of the sensing antennas as well as the set of reference antennas should be chosen such that the condition number of Q·D is minimized.

More generally, each distinct multipath component carries independent information about the pattern (and consequently the VSH composition) of the antenna. Thus we can view the preferred sensing antenna locations as those that maximize the information capacity of the channel matrix. If we view the vector of VSH amplitudes a as the signal transmitted by the antenna, and the set of voltages v received by the sensing antennas as the received signal, then we can define an effective channel matrix as T≡Q·D. The E-capacity is the maximum information that can be transmitted through the channel matrix T in the presence of an uncertainty level of ∈. The ∈-entropy gives an upper bound to the ∈-capacity, and is given by [46]:

$${H}_{ϵ} ( T ) = \frac{1}{2} {log}_{2} ( \frac{det ( T \cdot {T}^{†} )}{{ϵ}^{2}} ) = {\sum }_{k = 1}^{{N}_{s}} {log}_{2} ( \frac{{σ}_{k}}{ϵ} ) , \qquad ( 53 )$$

where σₖ is the kth singular value of T. Regardless of the value of ∈, the upper bound on the capacity will be proportional to H₁. It is therefore desirable to maximize H₁, or equivalently to minimize:

f(T̅)=−det(T·T^{†}). (54)

Beyond maximizing H₁ or minimizing f, it is important to know whether or not the optimum value represents a matrix with sufficient degrees of freedom to approximate the VSH content with the required accuracy. It is likely that the Kolmogorov n-width can be used to obtain a quantitative estimate of the degrees of freedom in this context [47], but this requires additional exploration.

Note that if A_{R} is well conditioned, we could also consider the different reference antennas to be the inputs to a multiple-input multiple-output (MIMO) system (imagining that the reference antennas could be simultaneously energized at the same phase center location). In this case, V_{R} could be considered to play the role of the channel matrix. However, we are ultimately interested in how the VSH coefficients of the AUT map onto the measured sensor voltages, and the matrix Q·D takes into account both the diversity of the environment and the VSH diversity of the set of reference antennas.

### VIII. EXAMPLE: HALF-WAVE DIPOLE WITH ARBITRARY ORIENTATION IN A RANDOM MULTIPATH ENVIRONMENT

A. Half-Wave Dipole with Arbitrary Orientation

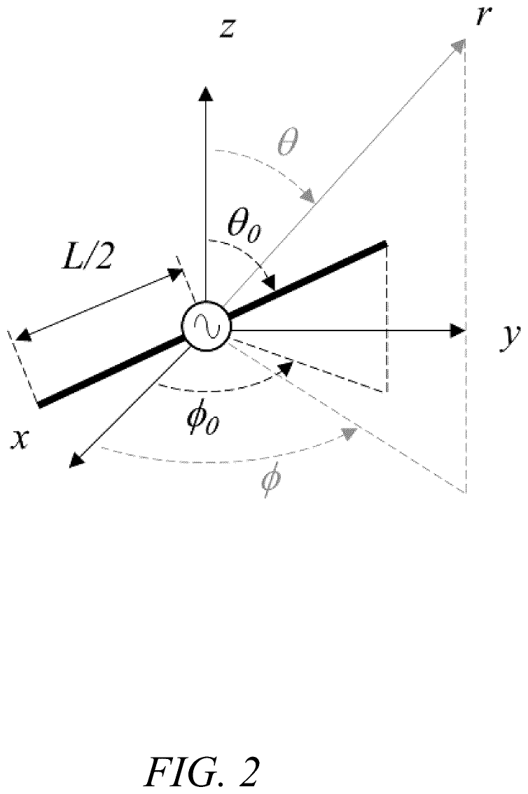

Consider the case of antennas that are center-fed dipoles of various lengths and orientations. The geometry is shown in FIG. 2. Explicit expressions for the electric field are given in the section below entitled, “Electric Field of Arbitrarily Oriented Dipole”. As a simple example, suppose that we limit our test antennas to half-wavelength dipoles (i.e., L=λ/2), but at some arbitrary orientation. Using the simplest estimate of Λ from Eq. (49) gives Λ=2,N_{Λ}=16, since the smallest radius enclosing the antenna would be R=L/2=λ/4. In contrast, the more conservative estimate (51) gives Λ=⁴,N_{Λ}=48. However, since we know that this antenna only has electric multipole equivalent sources, we could reduce our estimate to N_{Λ} ≈8 or N_{Λ} ≈24. In the case of the half-wave electric dipole, the pattern symmetry allows us to further reduce the required number of coefficients. In particular, the coefficients vanish for even values of A, so it is sufficient for us to consider the case Λ=3.

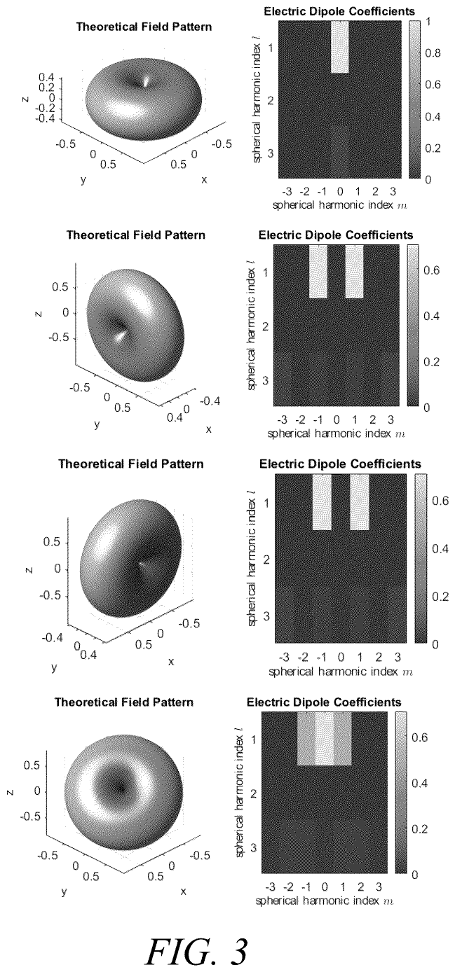

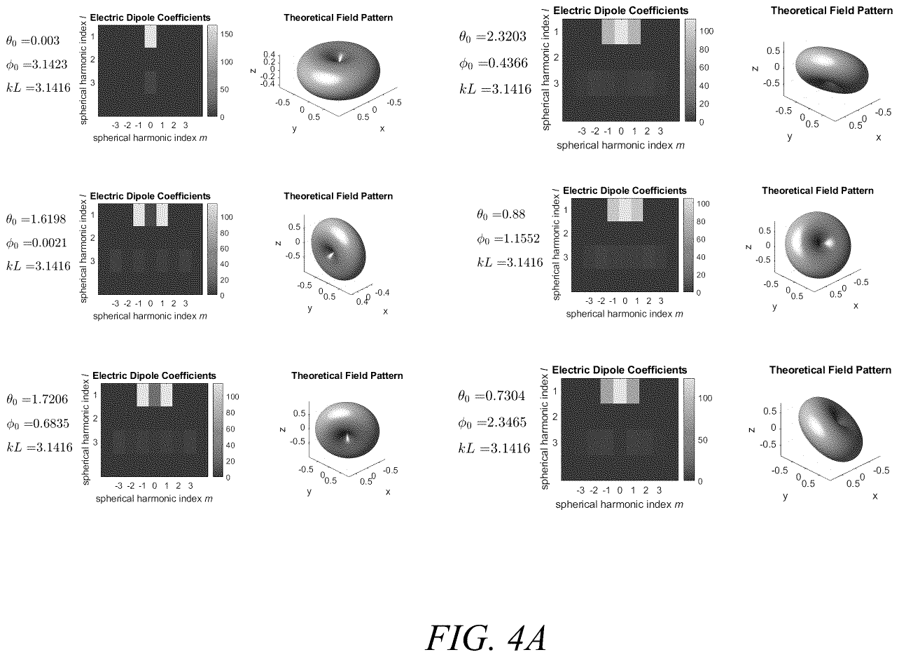

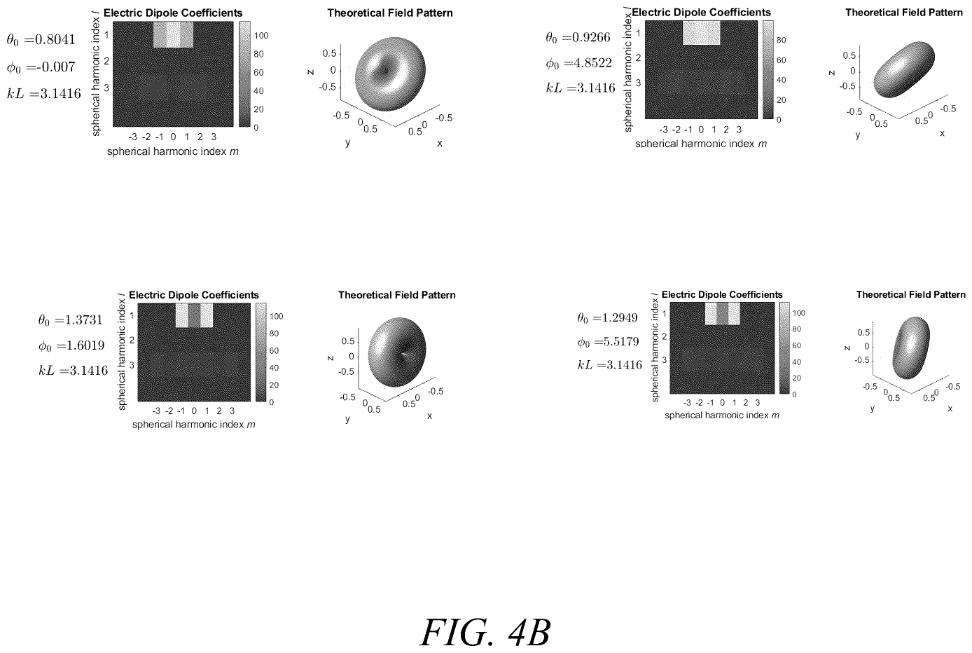

FIG. 3 shows the normalized patterns and spherical harmonic spectra for Λ=3 for several orientations. Referring to the spectra, we see that the significant terms (l,m)=(1,0), (1, ±1) are indeed covered if we were to take Λ=2 as given by Eq. (49). In this case only 3 spherical harmonic amplitudes are needed, and the top three orthogonal orientations in FIG. 3 can be used as calibration antennas. FIGS. 4A and 4B illustrate example properties of a set of dipole antennas.

However to ensure a more accurate representation, we do see some contributions from (l,m)=(3,0), (3, ±1), (3, ±2), (3, ±3) as well. Since the symmetry of the dipole patterns results in no components for l=2, the total number of spherical harmonic amplitudes we need for Λ=3 is 10.

In view of the relation between coefficients with values of +m given by (18), it may appear that the actual number of coefficients is smaller. However, counting the real and imaginary parts of a coefficient as independent unknowns, there are equivalently 10 real unknowns to be determined.

To obtain the amplitudes of 10 spherical harmonics, we need 10 calibration antennas whose spherical harmonic spectra are known, whose vectors of spherical harmonic amplitudes are linearly independent, and whose spectra illuminate the 10 spherical harmonics needed to properly reproduce an arbitrary half-wave dipole pattern. One possible choice for a set of calibration antennas is to use center-fed dipoles with various lengths and orientations. For simplicity, we consider ten identical half-wave dipoles but with different orientations, as shown in FIGS. 4A and 4B. The orientations of these calibration antennas were optimized to a local minimum of cond(A) using the MATLAB function fminsearch. The minimum value obtained was cond(A)=41.22, which is still rather large considering that a well-conditioned matrix would have cond(A)≈1. The larger condition number indicates that the matrix inverse process in Eq. (40) will be sensitive to small errors in A, increasing the error of the pattern reconstruction. Clearly there is opportunity to improve the set of calibration antennas, but this set proves to be sufficient to illustrate the concept.

To calculate the spherical harmonic spectra of these antennas from first principles using Eqs. (27) and (28), we need the magnitude of the current at the antenna terminals, I₀, to determine the strength of the electric field. For simplicity, we will assume the antennas are fed with a lossless transmission line with characteristic impedance Z₀, and that the antennas are operated at resonance so that the terminal impedance Rₐ is real. Under these assumptions the current at the terminals of the antennas is given by

$${I}_{0} = \sqrt{\frac{2 {P}_{i n c}}{{Z}_{0}}} ( 1 - Γ ) = \frac{2 \vert {V}_{i n c} \vert}{{R}_{a} + {Z}_{0}} , \qquad ( 55 )$$

where P_{inc} is the power incident from the source, V_{inc} is the voltage of the incident wave on the transmission line to the antenna, and the reflection coefficient (assumed real as indicated above) is given by

$$Γ = \frac{{R}_{a} - {Z}_{0}}{{R}_{a} + {Z}_{0}} . \qquad ( 56 )$$

Note that if all of the calibration antennas and the test antenna have the same impedance, then the currents will all be the same and this calculation is not necessary. However, if any of the calibration/reference or test antennas have different terminal impedances, then the received signals need to be normalized to equivalent terminal currents in all of the antennas.

### B. Random Multipath Environment

Let us model the voltage at the kth antenna probe as

$${V}_{k} = {\sum }_{n = 1}^{{N}_{p}} ρ k , n [ {E}_{θ} ( {θ}_{0} , {ϕ}_{0} , {θ}_{k , n} , {ϕ}_{k , n} ) cos {α}_{k , n} + {E}_{ϕ} ( {θ}_{0} , {ϕ}_{0} , {θ}_{k , n} , {ϕ}_{k , n} ) sin {α}_{k , n} \qquad ( 57 )$$

Here ρ_{n,k} represents the overall complex amplitude of the nth path to the k th antenna probe; θ₀,φ₀ represent the orientation of the axis of the dipole antenna being tested; θ_{k,n},φ_{k,n}, represent the launch direction from the test antenna of the nth path to the kth antenna probe; and α_{k,n} represents a polarization mixing angle owing to geometry and scattering along the nth path to the kth antenna probe. The parameters ρ_{k,n},θ_{k,n},φ_{k,n},α_{k,n} are taken to be random variables with distributions as described in Table I.

TABLE I
Parameters for the random multipath environment model.

| Parameter | Distribution |
|---|---|
| ρ_{k, n} | Normal, (μ = 0, σ_{ρ}), σ_{ρ} chosen to represent received signal |
| | amplitude |
| θ_{k, n} | Uniform, (0, π) |
| φ_{k, n} | Uniform, (0, 2π) |
| α_{k, n} | Uniform, (0, 2π) |

This model was implemented with 10×10 random matrices for each of the path parameters in Table I, and σₚ=0.001. The probe voltages vₖ were then calculated for each one of the reference antennas to create the square matrix V. Since there is no physical model underlying the path parameter matrices, 100 sets of random path parameters were generated, and the set that yielded the lowest cond(V) was kept for the demonstration model. The matrix Q·D was then calculated from Eq. (40). For the path parameters selected, cond(V)=164.3, and cond(Q·D)=9.23. Although the matrices were generated numerically from Eq. (57) for the present example, it is also possible to obtain an analytical approximation for Q·D in terms of the model parameters, as shown in the section below entitled, “Q-D From Random Path Model”.

Owing to errors from ill-conditioned matrices (or experimental error in the case of measurements), the property (18) may not be satisfied by the direct calculation from Eq. (36). Consequently, this property was imposed numerically using the calculation

$${\hat{a}}_{l , m} = \frac{1}{2} [ {a}_{l , m} + {( - 1 )}^{m} {a}_{l , - m}^{*} ] , \qquad ( 58 )$$

$${\hat{a}}_{l , - m} = {( - 1 )}^{m} {\hat{a}}_{l , m}^{*} , \qquad ( 59 )$$

where the directly-calculated values are a_{l,m} and corrected values are denoted by â_{l,m}.

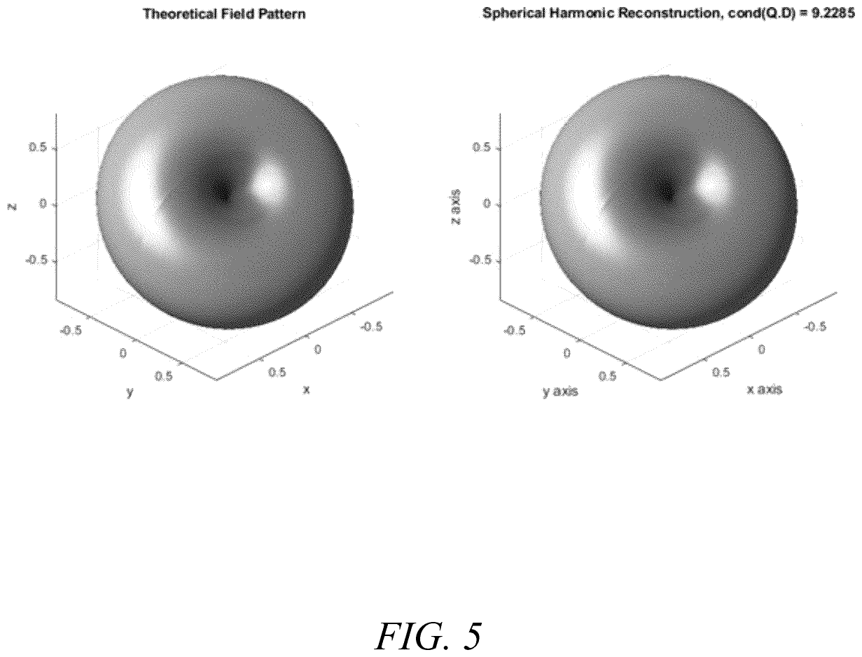

An example reconstruction for a test antenna orientation of θ₀=π/4, φ₀=π/3 is shown in FIG. 5, and the resulting estimates of field magnitude error, radiation resistance, and directivity are shown in Table II. The RMS field error was calculated by taking the difference between the theoretical and reconstructed field magnitudes at each sampled direction, normalizing the difference by the maximum magnitude of the theoretical field magnitude, and then calculating the square root of the mean of this normalized difference over all the sampled directions. The directivity error is simply the difference between the theoretical directivity and the directivity obtained from the reconstructed pattern.

TABLE II: Field magnitude error, radiation resistance, and directivity
for an example case compared with the theoretical results.

| | RMS Field Error | Rᵣ (Ω) | Directivity |
|---|---|---|---|
| Theory | — | 73.1 | 1.64 (2.15 dB) |
| Reconstruction | 7.86 × 10⁻⁴ | 73.1 | 1.64 (2.15 dB) |
| θ₀ = π/4, φ₀ = π/3 | | | |

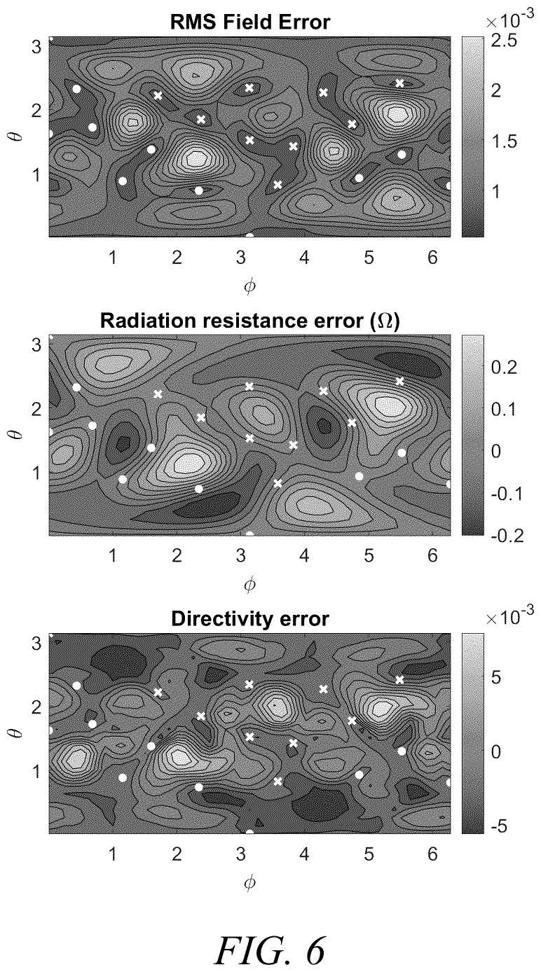

The accuracy of the reconstruction can be seen to be quite good. This is to be expected since the only source of error is numerical error from the MATLAB computation. The errors in field magnitude, radiation resistance, and directivity over the full range of test antenna orientations are shown in FIG. 6.

Note that each set of random parameters can be viewed as corresponding to a particular set of probe antenna locations in the environment. It follows that some configurations of antennas give better-conditioned matrices than others. In an experimental facility designed to use this method for constructing patterns, attention must be given to optimizing the placement of the probe antennas.

### IX. SUMMARY AND CONCLUSIONS

This work introduced a technique for measuring antenna patterns that constructively uses multipath propagation in the environment. As a result, the need for costly anechoic chambers is eliminated. Vector Spherical Harmonics are used as an efficient representation of the pattern, minimizing the number of required measurements and reference antennas. Example calculations to illustrate the method have been presented.

### Expressions for Vector Spherical Harmonics

$${X}_{l , m} = \frac{- j}{\sqrt{l ( l + 1 )}} [ \hat{ϕ} \sqrt{\frac{( 2 l + 1 ) ( l - m ) !}{4 π ( l + m ) !}} \times [ \frac{l cos θ {P}_{l}^{m} ( cos θ ) - ( l + m ) {P}_{l - 1}^{m} ( cos θ )}{\sqrt{1 - {cos}^{2} θ}} ] {e}^{j m ϕ} - \hat{θ} \frac{j m}{sin θ} {Y}_{l , m} ] , \qquad ( 60 )$$

$$\hat{r} \times {X}_{l , m} = \frac{j}{\sqrt{l ( l + 1 )}} [ \hat{θ} \sqrt{\frac{( 2 l + 1 ) ( l - m ) !}{4 π ( l + m ) !}} \times [ \frac{l cos θ {P}_{l}^{m} ( cos θ ) - ( l + m ) {P}_{l - 1}^{m} ( cos θ )}{\sqrt{1 - {cos}^{2} θ}} ] + {e}^{j m ϕ} + \hat{ϕ} \frac{j m}{sin θ} {Y}_{l , m} ] . \qquad ( 61 )$$

### Electric Field of Arbitrarily-Oriented Dipole

Referring to the geometry shown in FIG. 2, the electric field from a center-fed dipole of arbitrary length and orientation is given by

$$E = - j \frac{{η}_{0} {I}_{0} {e}^{- jkr}}{2 π r} ( \hat{θ} p + \hat{ϕ} q ) \times [ \frac{cos ( \frac{kLg}{2} ) - cos ( \frac{kL}{2} )}{1 - {g}^{2}} ] , \qquad ( 62 )$$

$$where$$

$$p = sin {θ}_{0} cos {ϕ}_{0} cos θcos ϕ + sin {θ}_{0} sin {ϕ}_{0} cos θsin ϕ - cos {θ}_{0} sin θ , \qquad ( 63 )$$

$$q = sin {θ}_{0} sin {ϕ}_{0} cos ϕ - sin {θ}_{0} cos {ϕ}_{0} sin \qquad ( 64 )$$

$$g = sin {θ}_{0} cos {ϕ}_{0} sin θ cos ϕ + sin {θ}_{0} sin {ϕ}_{0} sin θsin ϕ , + cos {θ}_{0} cos θ . \qquad ( 65 )$$

### Q·D from Random Path Model

Here we show that it is possible to analytically construct an approximation to Q·D for the random path model. Since there are only electric dipole components of the antennas, Eq. (14) simplifies to

$$E ( {θ}_{0} , {ϕ}_{0} , θ , ϕ ) = - {η}_{0} {\sum }_{l , m} {( j )}^{l + 1} {a}_{l , m}^{E} \hat{r} \times {X}_{l , m} = - {η}_{0} {\sum }_{l , m} {( j )}^{l + 1} {a}_{l , m}^{E} [ {\hat{θ} ( \hat{r} \times {X}_{l , m} )}_{θ} + {\hat{ϕ} ( \hat{r} \times {X}_{l , m} )}_{ϕ} ] \qquad ( 66 )$$

$$or$$

$$E ( {Ω}_{0} , Ω ) ≡ - {η}_{0} {\sum }_{q = 1}^{{N}_{A}} {( j )}^{{l}_{q} + 1} {a}_{q}^{E} ( {Ω}_{0} ) [ \hat{θ} {Θ}_{{l}_{q} , {m}_{q}} ( Ω ) + \hat{ϕ} {Φ}_{{l}_{q} , {m}_{q}} ( Ω ) ] . \qquad ( 67 )$$

Here we have replaced the two-dimensional sum with a one-dimensional sum using the mapping shown in Table III; explicitly indicated that the dependence of the dipole orientation Ω₀ is contained in the spherical harmonic amplitudes while the dependence on the path launch angle Ω is contained in the spherical harmonic functions; omitted the pre-factor in view of the complex amplitude ρ_{m,n}; and we have introduced the short-hand notations

θ,φ→ (68)

(\hat{r}×xₗ_{_{q}}_{,M}_{_{q}})_{θ}→Θₗ_{_{q}}_{,M}_{_{q}}(Ω) (69)

(\hat{r}×xₗ_{_{q}}_{,M}_{_{q}})_{φ}→Φₗ_{_{q}}_{,M}_{_{q}}(Ω) (70)

TABLE III
Mapping from the sum over (l, m) to a single sum over q

| q | l | m |
|---|---|---|
| 1 | 1 | −1 |
| 2 | 1 | 0 |
| 3 | 1 | 1 |
| 4 | 3 | −3 |
| 5 | 3 | −2 |
| 6 | 3 | −1 |
| 7 | 3 | 0 |
| 8 | 3 | 1 |
| 9 | 3 | 2 |
| 10 | 3 | 3 |

Further, we have omitted the factor exp(−jkr)/(kr) in both (14) and (17), since this factor cancels when the equations are combined.

Substituting (67) into (57) allows us to write

$${v}_{k} = - {η}_{0} {\sum }_{q = 1}^{{N}_{A}} {a}_{q}^{E} ( {Ω}_{0} ) {( j )}^{{l}_{q} + 1} \times {\sum }_{n = 1}^{{N}_{p}} {ρ}_{k , n} [ {Θ}_{{l}_{q} , {m}_{q}} ( {Ω}_{k , n} ) cos {α}_{k , n} + {Φ}_{{l}_{q} , {m}_{q}} ( {Ω}_{k , n} ) sin {α}_{k , n} ] ≡ {[ Q \cdot D \cdot a ]}_{k} , \qquad ( 71 )$$

$$where$$

$${[ Q \cdot D ]}_{k , q} = - {{η}_{0} ( j )}^{{l}_{q} + 1} {\sum }_{n = 1}^{{N}_{p}} {ρ}_{k , n} [ {Θ}_{{l}_{q} , {m}_{q}} ( {Ω}_{k , n} ) cos {α}_{k , n} + {Φ}_{{l}_{q} , {m}_{q}} ( {Ω}_{k , n} ) sin {α}_{k , n} ] . \qquad ( 72 )$$

Note that estimating Vₖ using Eq.(71) will not yield exactly the same result as Eq. (57) if the exact expression for the electric field is used, since (71) uses an approximation to the electric field obtained by truncating the vector spherical harmonic series.

### Example System and Method

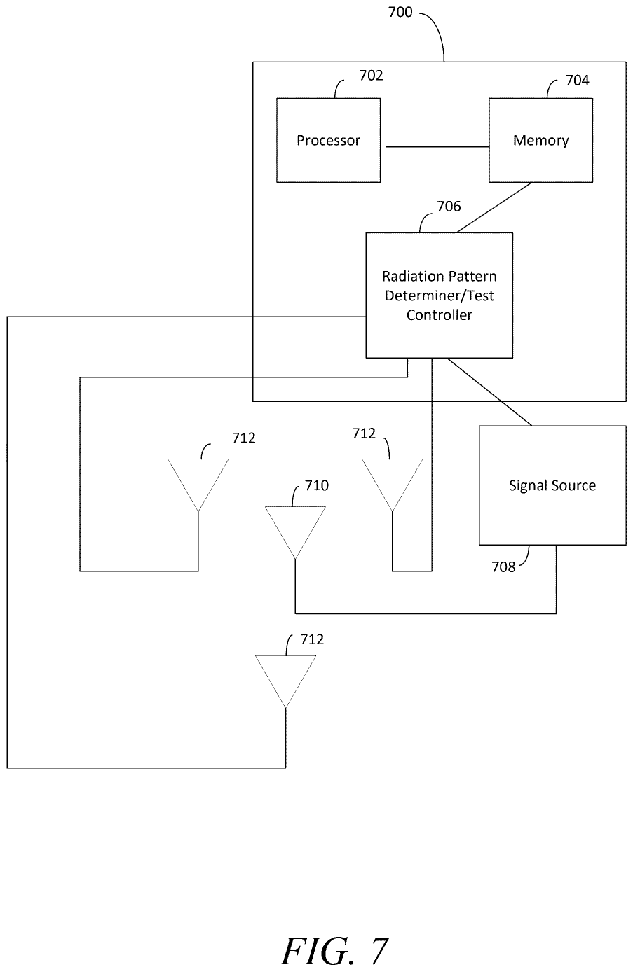

FIG. 7 is a block diagram illustrating an exemplary system for multipath enhanced measurement of antenna radiation patterns. Referring to FIG. 7, the system includes a computing platform 700 and including at least one processor 702 and memory 704. The system further includes a radiation pattern determiner/test controller 706 for controlling a signal source 708 to apply a signal to an antenna under test 710. Radiation pattern determiner/test controller 706 also receives signals detected by sensing antennas 712 and determines, from the signals received from sensing antennas 712, a radiation pattern of antenna under test 710. In one example, radiation pattern determiner/test controller 706 may be implemented using computer executable instructions stored in memory 704 and executed by processor 702. Signal source 708 may be any suitable electrical signal source for generating a signal to be applied to an antenna. One example of such a signal source is a waveform generator. Antenna under test 710 and sensing antennas 712 may be any suitable type of antennas capable of radiating electromagnetic fields. As described above, antenna under test 710 and sensing antenna 712 may be located in a non-anechoic environment, such as a room, a waveguide, or a reverberation chamber.

An example experiment for measuring radiation patterns of an antenna under test in a multipath environment is described in the section below under the heading, “Multipath-Enhanced Measurement of Antenna Patterns: Experiment”. An example of theory for measuring antenna radiation patterns in a multimode waveguide is described in the section below under the heading, “Multipath-Enhanced Measurement of Antenna Patterns in a Multimode Waveguide,” the disclosure of which is incorporated herein by reference in its entirety.

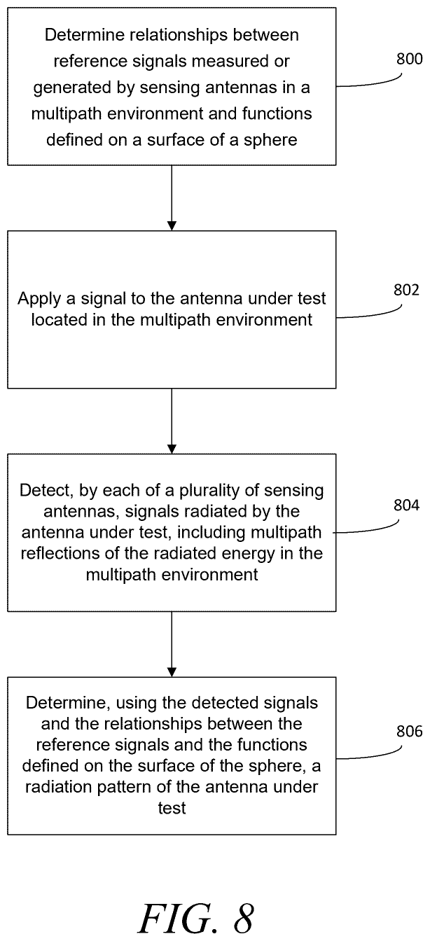

FIG. 8 is a flow chart illustrating an exemplary process for multipath-enhanced measurement of antenna radiation patterns. Referring to FIG. 8, in step 800, the process includes determining relationships between reference signals measured or generated by sensing antennas in a multipath environment and functions defined on a surface of a sphere. For example, a reference antenna with a known radiation pattern may be placed in a multipath environment and excited with a signal. Sensing antennas may detect signals radiated by the reference antenna, and the known radiation pattern at each sensing antenna may be used to determine a coupling, i.e., a mathematical relationship, between the signal detected at each sensing antenna, multipath reflections, and functions defined on the surface of a sphere. In one example, the functions defined on the surface of the sphere comprise vector spherical harmonics. In a reciprocal example, the sensing antennas may radiate, the reference antenna may detect the radiation, and the coupling may be determined based on the reference signals detected by the reference antenna.

In step 802, the process further includes applying a signal to the antenna under test located in the multipath environment. For example, the signal source may be used to apply a signal to an antenna under test located in a multipath environment.

In step 804, the process further includes detecting, by each of a plurality of sensing antennas, signals radiated by the antenna under test, including multipath reflections of the radiated energy in the multipath environment. For example, sensing antennas located around the signal under test may detect signals radiated by the antenna under test and multipath reflections of those signals.

In step 806, the process further includes determining, using the detected signals and the relationships between the reference signals and the functions defined on the surface of the sphere, a radiation pattern of the antenna under test. For example, radiation pattern determiner/test controller 706 may invert the coupling determined in step 800 to determine the radiation pattern of the antenna under test.

### Multipath-Enhanced Measurement of Antenna Patterns: Experiment

In the sections above we present the theory for an antenna pattern measuring technique that uses (rather than mitigates) the properties of a multipath environment. Here we use measurements in a typical home garage, a university research lab, and an anechoic chamber with and without scattering objects to experimentally demonstrate the feasibility of the technique. A half-wavelength electric dipole with different orientations was used as both the calibration and test antennas. For simplicity, we limited the modeling of the antenna pattern to using only the three I=1 vector spherical harmonics. Three methods were used to analyze the measurements: a matrix inversion method using only 3 sense antennas, a least-square-error technique, and a least-square-error technique with a constant power constraint imposed. The two least-square-error techniques used the measurements from 10 sense antennas. The constrained least-square-error technique was found to give the best results.

### I. INTRODUCTION

Traditional techniques for measuring antenna patterns re-quire minimizing or mitigating the effects of multipath propagation in the environment [48], [49]. In addition to constructing anechoic chambers, example techniques include time-gating to retain only the direct path [3]-[8], fitting complex exponentials to the response [1]-[4], [50], applying equalization techniques similar to those used in communications channels [12], making test zone field (TZF) measurements on the surface of a sphere enclosing the antenna under test (AUT) [10], [11], and averaging out multipath in reverberation chambers using stirrers [13]-[18]. A more complete summary of approaches is given in the theory section above.

In the theory section above, a technique that uses the multipath propagation to obtain pattern information has been introduced. This should enable pattern measurements without the need for costly anechoic environments. In contrast, the new method does not require a minimum bandwidth, com-plex positioning systems to measure the TZF, or a specially constructed environment, such as an anechoic chamber or reverberation chamber with stirrers. Similar to measurements on a sphere enclosing the antenna, the method yields the complete 3D pattern in one set of measurements. However, the new method does require a set of reference antennas that properly illuminate the spherical harmonic space needed to describe arbitrary AUTs contained in a specified volume.

In this work we demonstrate the feasibility of the technique using measurements in a typical home garage and a university laboratory. In addition, measurements were made in an anechoic chamber with and without added reflecting panels to explore the role of multipath propagation.

### II. DESCRIPTION OF EXPERIMENT

### A. Measurement System

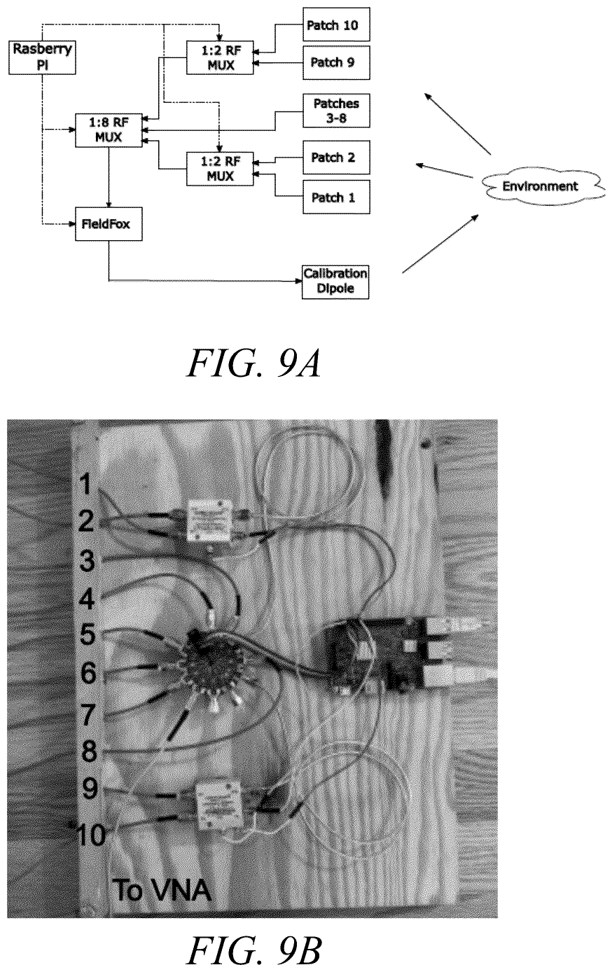

To experimentally verify the ideas, we constructed a test system to analyze the case for a half-wave dipole with arbitrary orientation. Based on the discussion in the theory section above, the system was designed to use up to 10 independent test antenna orientations to form the calibration matrix. An RF measurement system for making the measurements at an operating frequency of 3 GHz is shown in FIGS. 9A and 9B. Arbitrarily oriented patch antennas were used for the 10 sense antennas.

The 1:2 multiplexers used are a Minicircuits ZFSWA2R-63DR+ and a ZFSWA2-63DR+ (the difference is that the order of the output connectors is interchanged), and an evaluation board for an Infineon BGSF110GN26 (SP10T switch) was used for the 1:8 multiplexer. (Although the Infineon chip has 10 channels, two of these have low-pass filters below our selected operating frequency and hence could not be used.) RF measurements were made using a Keysight FieldFox® vector network analyzer under the control of a Raspberry Pi® 3B+ microprocessor. Crosstalk between channels in the multiplexer system was characterized by connecting the FieldFox output to each patch antenna input in turn and measuring the response at the multiplexer input while stepping through the multiplexer channels. During these measurements, the unexcited patch antenna inputs were terminated in 50 Ohm loads. If v is the vector of true voltages at the patch antenna inputs, then the measured voltage vector vₘ is given by

vₘ=Mₓ·v, (73)

where Mₓ is the measured cross-talk matrix. It follows that estimates of the true voltages can be recovered with the calculation

v=Mₓ⁻¹·vₘ. (74)

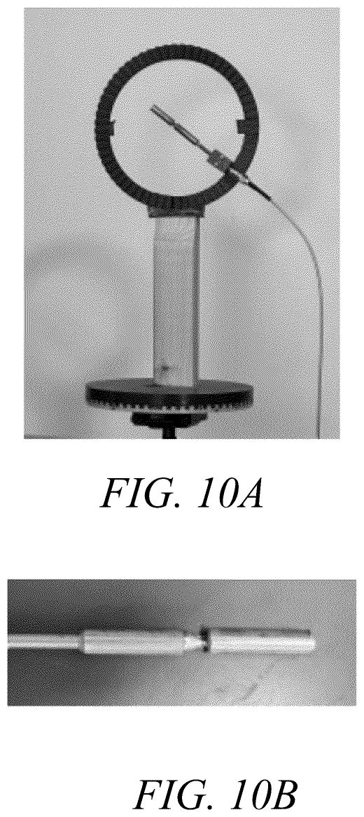

A sleeve dipole with different orientations was used for both calibration as well as the antenna under test. Two dipoles were fabricated as identical as possible. One of the sleeve dipoles mounted on a custom goniometer is shown in FIGS. 10A and 10B. The goniometer enabled discrete angular orientations in steps of 6 degrees. A close-up view of the sleeve dipole used in the garage and lab measurements is shown in FIG. 10B. A second copy of the dipole was used in the anechoic chamber measurements. With this system measurements were made in three environments: a household garage, a university research lab, and an anechoic chamber with and without metallic reflectors. We now describe these measurements in more detail.

### B. Household Garage

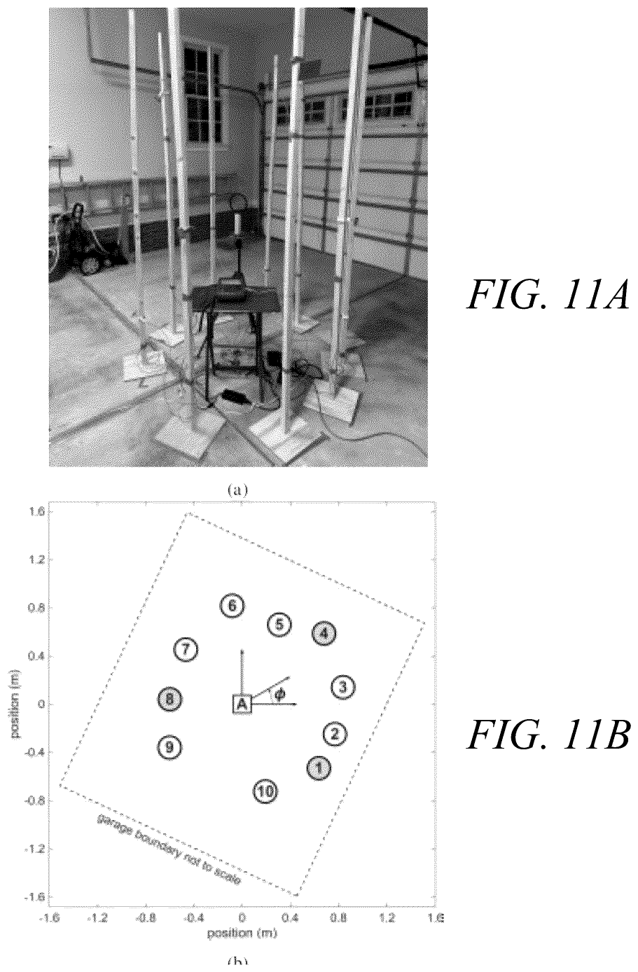

As a first case, measurements were made in a garage with a metal garage door, with no steps taken to reduce reflections. The setup is shown in FIG. 11A. The patch antennas can be seen mounted at different heights and orientations on the wooden posts surrounding the test antenna which is mounted on a tripod.

A plan view approximately to scale (the precise locations were not measured) is shown in FIG. 11B. Other than wanting to represent a variety of heights and directions, there was no pattern to the choice of patch antenna locations.

Ten test antenna orientations were used in anticipation of a full analysis of the electric dipole as discussed above. How-ever, as a first demonstration of the concept, we approximated the dipole with the three strongest harmonics for l=1. This only required 3 calibration antennas, which we chose as the dipole oriented along the three orthogonal axes.

TABLE IV
Antenna heights

| Ant No. | Garage | | Lab | Chamber |
|---|---|---|---|---|
| AUT | 1.2 | m | 1.12 m | 1.12 m |
| 1 | 2 | m | 1.14 m | 0.89 m |
| 2 | 1.2 | m | 1.47 m | 0.3 m |
| 3 | 0.37 | m | 2.03 m | 1.19 m |
| 4 | 1.2 | m | 0.66 m | 0.41 m |
| 5 | 2 | m | 1.68 m | 1.96 m |
| 6 | 0.37 | m | 1.09 m | 2.03 m |
| 7 | 1.2 | m | 1.93 m | 1.55 m |
| 8 | 2 | m | 0.36 m | 1.73 m |
| 9 | 0.37 | m | 1.46 m | 0.48 m |
| 10 | 1.2 | m | 1.75 m | 1.65 m |

A set of 10 orientations was generated in addition to the calibration antenna orientations to serve as antenna under test (AUT) cases. These are listed in the left columns of Table V. These orientations were selected to represent a reasonably complete coverage of the sphere. Although the reference antennas and the AUTs are realized by different orientations of the same sleeve dipole, we will frequently refer to these as if they were separate antennas for convenience (e.g., “antenna reference orientations” may be referred to interchangeably as “reference antennas”).

The sensing/patch antenna locations used three sets of heights: 3 above the test antenna, 3 below the test antenna, and 4 approximately at the same height as the test antenna. The patch mounting brackets could be set so that the direction perpendicular to the plane of the patch is either in the horizontal direction, or at angles of ±45 degrees from horizontal. The angle was initially chosen for each patch antenna that most nearly directed the main lobe of the patch antenna pattern toward the test antenna. However, to emphasize the role of multipath, the wooden posts were then rotated by about 180 degrees so that the patch antennas were outward facing instead of pointing toward the antenna.

### C. Laboratory and Anechoic Chamber

To illustrate the applicability of this measurement technique in environments with different multipath characteristics, similar measurements were also conducted in a university laboratory and an anechoic chamber. Measurements in the anechoic chamber were made with and without added metallic reflectors to explore the role of multipath.

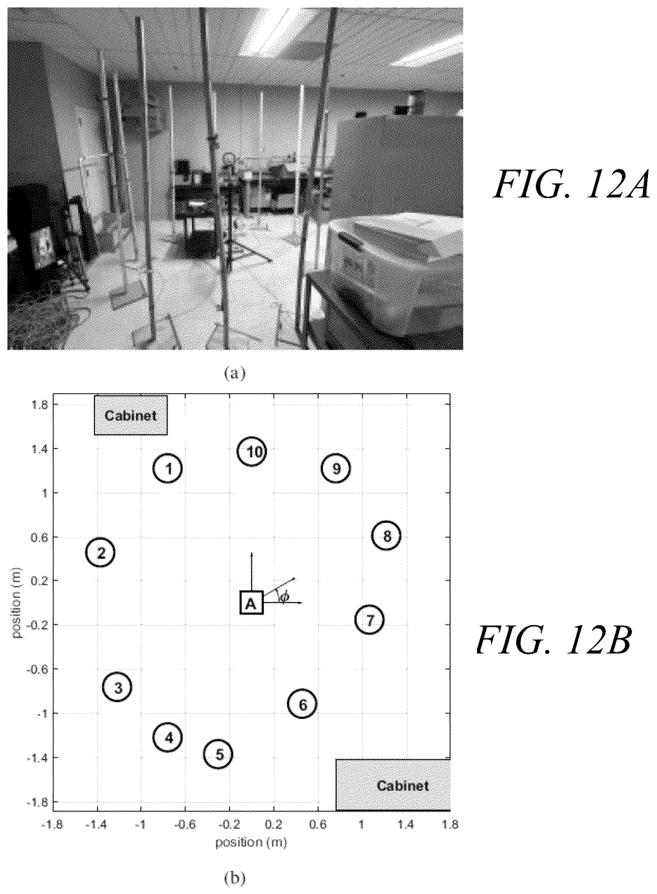

A photo of the lab setup is shown in FIG. 12A, and an approximate layout of the sense antennas is shown in FIG. 12B. The locations of a few large metal scatterers (e.g. metal cabinets) located near the sensor antennas were also recorded in the approximate layout of the laboratory setup.

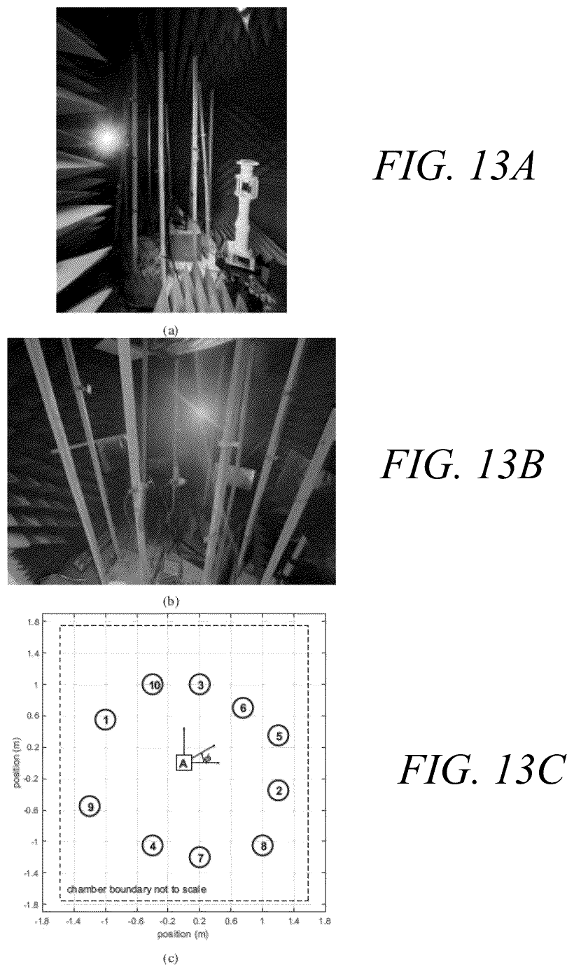

Similarly, a photo of the anechoic chamber setup showing the configuration without reflectors is shown in FIG. 13A. Ten aluminum reflectors of various sizes were placed around the anechoic chamber room as shown in FIG. 13B to introduce additional multipath into the anechoic environment, including above and below the test antenna. As with the other setups, an approximate layout of the sense antennas in the anechoic chamber is shown in FIG. 13C.

### III. ANALYSIS METHODS

Three methods of analysis were used, as described in the theory section above. We will refer to these as the Matrix Inversion (MI) method, the Least Square Error (LSE) method, and the Constrained Least Square Error (CLSE) method.

The general approach was to first take measurements of the sense antennas for each of a set of reference or calibration antennas, then take measurements on the antennas under test (AUT), and finally to determine the superpositions of the reference antenna signals that best approximate the of measurements of the AUTs. Since the vector spherical harmonic (VSH) composition of the reference antennas is assumed to be known, the weighted sum of these yields an approximation to the VSH components of the AUT, from which the pattern can be constructed.

As discussed in the theory section above, the key properties of the channel are represented by the matrix

$$T = {V}_{R} \cdot {A}_{R}^{- 1} ,$$

where V_{R} is the matrix containing the patch antenna measured voltages for the calibration antennas, and A_{R} is the matrix containing the VSH coefficients for the calibration antennas. Consequently obtaining the best result requires optimizing the choice of calibration antennas as well as the placement of the sense antennas (patches in the present case). However, since the matrix A_{R} is well conditioned in this case, we can consider V_{R} to represent the channel. We proceed by separating the process into two steps: the first is determining the weights of the reference antennas needed to construct the patch antenna voltages from the AUT, and the second is calculating the resulting VSH coefficients and patterns. The accuracy of this second step depends on the accuracy with which the VSH coefficients for the reference antennas are known. Measuring or calculating the coefficients of the reference antennas is an involved process on its own, so for illustration purposes, we will assume the VSH coefficients of our sleeve dipole at various orientations are the same as those of a thin half-wave dipole, as computed in the theory section above. The weight vector w associated with a particular AUT is related to the measured voltages at the patch antenna as

v=V_{R}·w. (75)

Because of the linearity of the system, this weight vector also determines the VSH coefficient vector a of the AUT:

a=A_{R}·w. (76)

Also, since the AUTs are represented simply by rotations, it is possible to write down the exact solution for the weights to compare with the experimental analysis:

wₙ=[w_{z,n},w_{x,n},w_{y,n}]^{T}=[cos θₙ,sin θₙ cos φₙ,sin θₙ sin φₙ]^{T}, (77)

where wₙ is the weight vector corresponding to the orientation (θₙ, θₙ), with the angles defined as in FIG. 2.

In the following sections we obtain estimates of the weight vector w^{e} using three methods. To evaluate the accuracy of our estimates, we introduce the weight rms error:

Δw_{RMS}\sqrt{(w^{e}−wₙ)^{T}·(w^{e}−wₙ)/N,} (78)

RMSE(dB)=20 log₁₀(Δw_{RMS}). (79)

with N=3 in our present case.

Once estimates of the weights are obtained, the VSH coefficient vectors are obtained from (76). The radiated power is then

$$P = \frac{{\vert {a}^{e} \vert}^{2}}{2 {η}_{0} {k}^{2}} \qquad ( 80 )$$

where η₀ is the impedance of free space, and k=2π/λ is the wave number. The radiation resistance can be obtained from the radiated power:

$${R}_{r} = \frac{2 P}{{\vert I \vert}^{2}} , \qquad ( 81 )$$

where I is the current at the terminals of the antenna.

### A. Matrix Inversion Method

Measurements of signals from the three calibration antennas were made at all 10 patch antennas. However, to obtain square matrices, 3 of the 10 must be selected, resulting in 120 possible choices. This was done by choosing the set of 3 patches that resulted in the maximum 1-entropy H₁ [46]

$${H}_{1} ( {V}_{R} ) = \frac{1}{2} {log}_{2} ( det ( {V}_{R} \cdot {V}_{R}^{†} ) ) , \qquad ( 82 )$$

where the † superscript represents the conjugate transpose. The weight estimates are then obtained from

$${w}^{e} = {V}_{R}^{- 1} \cdot v . \qquad ( 83 )$$

Also shown in the table are the resulting values of radiation resistance Rᵣ obtained from the weights, assuming AR corresponds to thin half-wave dipoles. The theoretical value is Rᵣ=72.9Ω, if only the l=1 VSH terms are included. The deviations from this value indicate errors in the amplitude of the reconstructed pattern. In addition to errors in pattern amplitude, orientation errors can occur as well. These errors become apparent when the pattern is plotted.

### B. Least-Square-Error Method

Unlike the Matrix Inverse method, the Least-Square-Error (LSE) method can make use of any number of sense antennas (in our case, patch antennas) that is greater than the number of needed VSH coefficients. From the theory section above, the LSE weight vector estimate is given by

$$w = {[ R e \{ {V}_{R}^{†} \cdot {V}_{R} \} ]}^{- 1} \cdot R e \{ {V}_{R}^{†} \cdot v \} . \qquad ( 84 )$$

Here V_{R} is a 10×3 matrix.

### C. Constrained Least-Square-Error Method

The RMS errors can be improved by imposing a constraint of constant power. For our calculations we used the form

w^{T}·w=1. (85)

The error minimization subject to this constraint was implemented with the MATLAB® function fmincon using the sqp algorithm. The equality constraint used expressed as a MATLAB® command was

ceq=w′*w−1;6 (86)

The constrained Least-Square-Error Method requires starting points for the optimization. The procedure used was to carry out the optimization with several starting points, then choose the solution corresponding to the lowest RMS error fit to the measured voltages from the AUT. The starting points used were the origin plus 8 points on the unit sphere as follows:

$${w}_{0} = [ \begin{matrix}0 & c & - c & c & - c & - c & c & c & - c \\ 0 & c & - c & - c & c & - c & - c & c & c \\ 0 & c & - c & c & - c & c & - c & - c & c\end{matrix} ] , \qquad ( 87 )$$

$$where c = 1 / √ 3.$$

### IV. RESULTS

### A. Garage Results

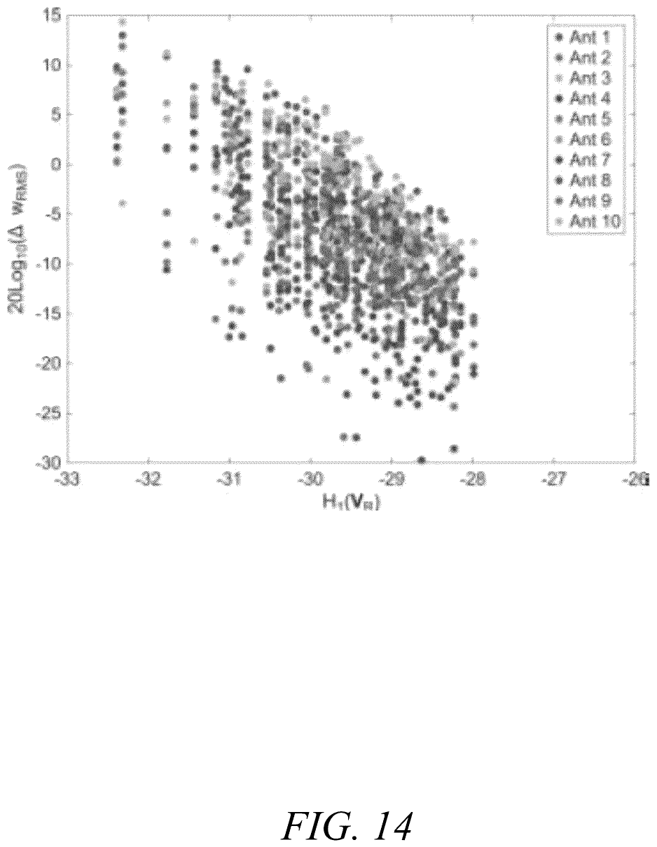

To verify that H₁ is indeed a useful metric, each of the 10 AUTs were evaluated for each of the 120 possible choices for V_{R} by calculating the rms error of the weight vector using (79). The results are shown in FIG. 14. Although there is significant scatter in the data, the trend of minimizing the error by maximizing the 1-entropy is clear. Another potential metric mentioned in the theory section above is cond(V_{R}). A comparison between the matrix condition and the 1-entropy is shown in FIG. 15. There is a clear correlation in that minimizing the condition number tends to maximize the 1-entropy. However, again there is statistical spread, and in fact the two metrics give different optimum patch antenna choices in our case. In our analysis, the set of patch antennas that maximized the 1-entropy was antennas 1, 4, and 8, as shown by the shaded circles in FIG. 11B. This set of antennas was used to calculate the weight estimates using Eq. (83). The results are shown in Table V.

The LSE and constrained LSE for each AUT along with the calculated radiation resistance are also given in Table V.

As can be seen in Table V, for the present case this constraint also ensured that the radiation resistance was equal to the theoretical value for the assumed calibration antennas. This is a consequence of the use of orthogonal calibration antennas.

### B. Lab and Anechoic Chamber Results

Noting that the constrained LSE method generally gives better results, a summary of these values for measurements in a university lab and an anechoic chamber are given in Table VI.

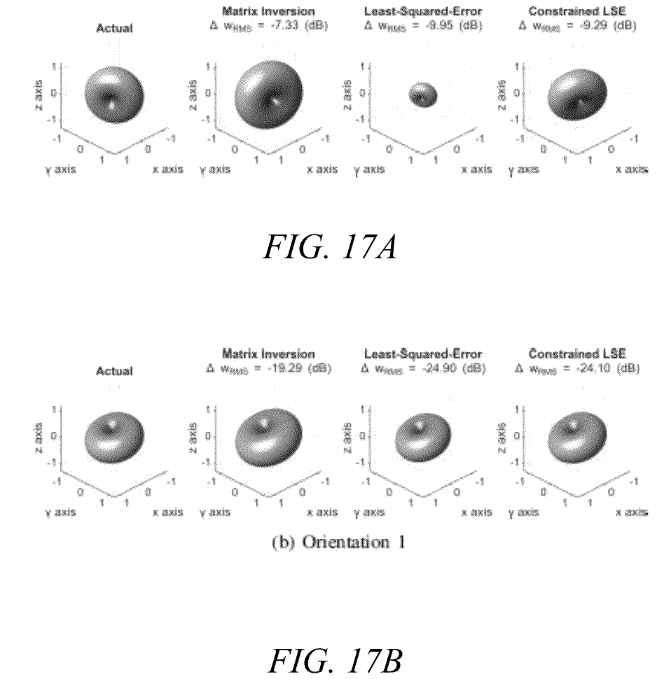

Example patterns for examples of the best and worst cases for the Lab measurements are shown in FIGS. 17A and 17B.

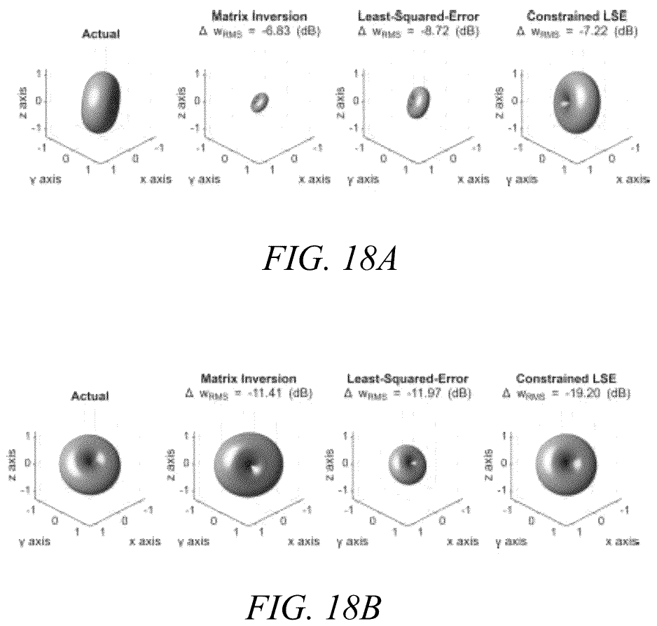

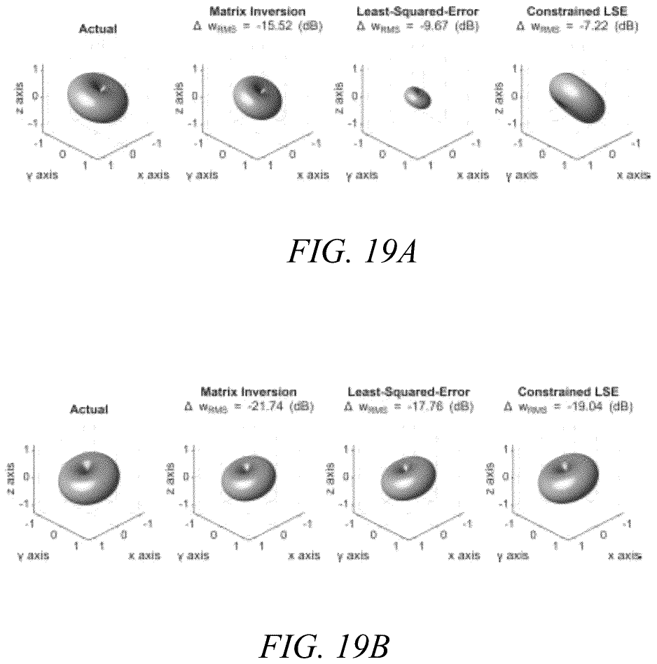

TABLE V
Summary of experimental results for garage measurements
Similarly, examples of the best and worst case patterns
for the two sets of anechoic chamber measurements are
shown in FIGS. 18A, 18B, 19A and 19B.

| | θ | φ | Matrix Inverse | | LSE | | Constrained LSE | |
|---|---|---|---|---|---|---|---|---|
| Orientation # | (deg) | (deg) | RMSE (dB) | Rᵣ (Ω) | RMSE (dB) | Rᵣ (Ω) | RMSE (dB) | Rᵣ (Ω) |
| 1 | 18 | 0 | −20.4 | 55.6 | −20.6 | 54.4 | −26.9 | 72.9 |
| 2 | 18 | 120 | −18.1 | 74.5 | −26.5 | 61.6 | −35.3 | 72.9 |
| 3 | 18 | −120 | −16.1 | 43.3 | −13.8 | 37.5 | −19.1 | 72.9 |
| 4 | 42 | 60 | −11.0 | 46.3 | −16.2 | 49.7 | −17.6 | 72.9 |
| 5 | 42 | 180 | −15.3 | 55.8 | −13.8 | 37.2 | −19.5 | 72.9 |
| 6 | 42 | −60 | −10.7 | 42.6 | −13.6 | 43.5 | −12.5 | 72.9 |
| 7 | 90 | 30 | −21.1 | 79.8 | −19.7 | 74.8 | −20.0 | 72.9 |
| 8 | 90 | 120 | −15.8 | 54.3 | −14.7 | 35.3 | −19.9 | 72.9 |
| 9 | 90 | 210 | −15.4 | 37.6 | −16.3 | 54.2 | −16.4 | 72.9 |
| 10 | 90 | −60 | −7.80 | 87.0 | −14.9 | 58.8 | −14.0 | 72.9 |
| mean values | | | −15.2 | 57.7 | −17.0 | 50.7 | −20.1 | 72.9 |

### V. DISCUSSION

From Table V, we see that the constrained LSE method generally gives the best result, while the Matrix Inversion method gives the least accurate. Although not a problem in this special example, the MI method would also have problems with ill-conditioned matrices if some of the VSH coefficients were zero or extremely small (see theory section above). This would likely often be the case when there is very little a priori knowledge about the VSH spectrum for the AUT.

TABLE VI: Summary of experimental results for
lab and anechoic chamber measurements. Values
given are for the constrained RMSE (dB)

| | | | | Anechoic | |
|---|---|---|---|---|---|
| | | | | Chamber (dB) | |
| | θ | φ | Lab | No | With |
| Orientation # | (deg) | (deg) | (dB) | Reflectors | Reflectors |
| 1 | 18 | 0 | −24.1 | −6.45 | −19.0 |
| 2 | 18 | 120 | −13.2 | −9.94 | −7.22 |
| 3 | 18 | −120 | −14.0 | −15.2 | −10.8 |
| 4 | 42 | 60 | −9.48 | −19.2 | −14.0 |
| 5 | 42 | 180 | −9.76 | −14.2 | −15.6 |
| 6 | 42 | −60 | −24.7 | −9.76 | −11.5 |
| 7 | 90 | 30 | −16.3 | −9.46 | −17.5 |
| 8 | 90 | 120 | −22.3 | −9.86 | −12.8 |
| 9 | 90 | 210 | −9.29 | −13.4 | −18.4 |
| 10 | 90 | −60 | −10.3 | −7.22 | −15.9 |
| mean values | | | −15.4 | −11.5 | −14.3 |

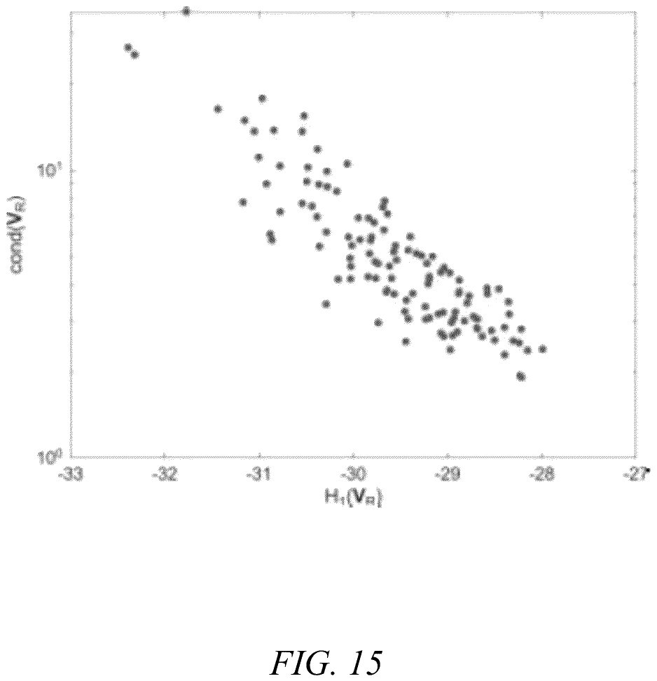

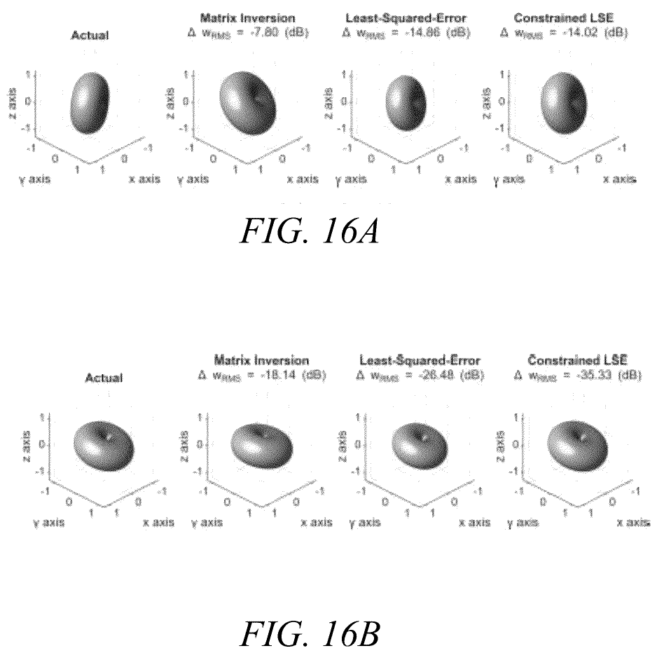

As mentioned previously, error contributions to RMSE (dB) come from both the amplitude and the orientation of the reconstructed pattern. The orientation errors can be best seen when the patterns are plotted (FIGS. 16A-19).

From Table V, we see that Orientation 10 had some of the largest errors for the garage measurements. The patterns corresponding to this case are shown in FIG. 16A. Errors in orientation are apparent in all three cases, and errors in amplitude can be seen in the MI and LSE cases.

In contrast, Orientation 2 had some of the lowest errors. Referring to FIG. 16B, while some errors are apparent in the MI and LSE cases, the Constrained LSE pattern is almost indistinguishable from the actual pattern.

Comparing the results between Table V and Table VI, we see that while the error is reasonable for some antenna orientations, the error for the lab setup is higher on average than in the garage.

The measurements in the anechoic chamber are interesting since they give an indication of the effects of multipath. Both sets of measurement in the chamber have higher mean error than in the garage and in the lab, where much richer multipath is present. Moreover, adding several reflecting panels to the chamber measurements improves the mean error by 2.8 dB.

Avenues to improve the accuracy of the measurements include the use of a precision goniometer and use of 1:N multiplexers with minimal crosstalk.

As suggested by the anechoic chamber measurements, it should also be possible to significantly improve these results by introducing more sources of multipath in the environment, and optimizing the placement of the sense antennas. This can be quantified by organizing the environment to maximize the 1-entropy. In the more general case where inclusion of VSHs with l>1 are needed, it will also be important to design calibration antennas to maximize the 1-entropy with

$${V}_{R} \cdot {A}_{R}^{- 1}$$

serving as the channel matrix in (82) instead of V_{R}.

It is important to note that the sensitivity to specific vector spherical harmonics can vary with sense antenna placement, and this could affect the accuracy of the representation of different antennas depending on their specific VSH content. Consequently, an important topic for future research is identifying sense antenna placements and environments that are satisfactorily sensitive to all VSH in the basis set. In such a case the same placement should work well for any antenna describable with the basis set. An important topic for future research is understanding the requirements of the multipath environment and the sense antenna placement to give consistently good results for an arbitrary AUT.

### VI. SUMMARY AND CONCLUSION

In contrast to conventional antenna pattern measurement methods that seek to minimize the effects of multipath propagation, we have demonstrated a technique that uses multipath propagation to construct the pattern. The approach can be considered similar to a MIMO channel where the inputs are the vector spherical harmonics of the antenna under test, and the outputs are the measured voltages at sense antennas distributed in the multipath environment. By characterizing the environment with a set of calibration antennas, the vector spherical harmonics of the antenna under test can be calculated from the measured sense antenna voltages. The pattern can then be constructed from the vector spherical harmonics. Because the required number of vector spherical harmonics increases rapidly with antenna size, it is likely that this method will be of most interest for characterizing small antennas (of order one wavelength or smaller) such as those typically used in consumer devices.

### Multipath-Enhanced Measurement of Antenna Patterns in a Multimode Waveguide

A new antenna pattern measurement technique that uses (rather than mitigates) the properties of a multipath environment has recently been reported. Here we describe how this technique can be implemented in a multimode waveguide. This implementation can be compact for small antennas such as those used on personal electronic devices. The completely enclosed environment eliminates concerns about changes or movements that can occur in open multipath environments.

### I. INTRODUCTION

Traditionally, anechoic environments are desired for measuring antenna patterns. If multi-path propagation is present, considerable effort is expended to eliminate its impact on the measurement. In addition to lining the environment with RF absorbing material, techniques that have been used include time gating [3] and averaging out time-varying multipath in a reverberation chamber [13]. A more detailed discussion of conventional techniques is described above in the theory section. In contrast, a new technique has recently been proposed that uses (rather than mitigates) multi-path propagation, which is also described above in the theory section. The technique was demonstrated in a non-anechoic environment (a residential garage) (see measurement section above).

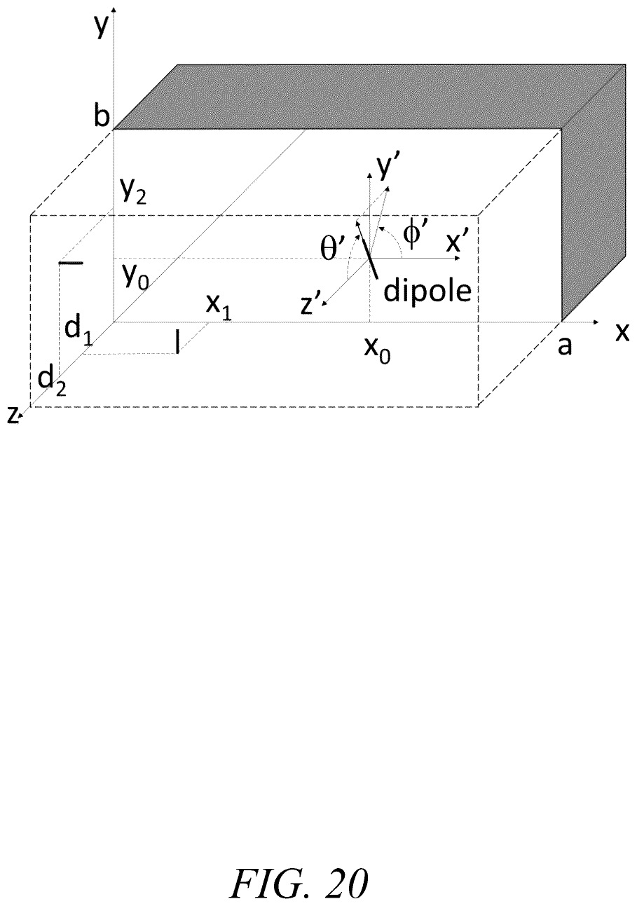

In this work, the case where the environment is a multimode rectangular waveguide is considered. We consider a dipole test antenna placed in the cross-section, and monopole probes as the sense antennas (see FIG. 20). This is a similar situation to the HVAC channel described by Nikitin, et al. [52]. Advantages over a general open multi-path environment include elimination of errors from movement or changes in the environment, and an easily reproducible configuration.

### II. FORMULATION OF THE APPROACH

The formulation is described in detail above in the theory section, but is outlined briefly here.

To efficiently represent the pattern of an antenna, we use an expansion in vector spherical harmonics (VSHs). The representation is efficient in that the number of VSH coefficients necessary is typically much smaller than the number of angular measurements needed for a smooth representation of the pattern using conventional measurement techniques. For example, the 3-D pattern of a half wavelength dipole can be represented well with 10 VSH coefficients. We assume the size of the antenna under test (AUT) is bounded, which band-limits the number of required VSH coefficients to N_{Λ}. The environment is experimentally characterized by measuring the response of Nₚ probe antennas placed throughout the environment to N_{Λ} reference antennas whose VSH expansions are known. The VSH coefficient vectors for the reference antennas must be linearly independent, and properly illuminate all VSH coefficients up to N_{Λ}. Under these assumptions, and if Nₚ=N_{Λ}, an estimate of the vector of VSH coefficients ae of an AUT is obtained from the vector of probe voltage measurements v^{TA} as

$${a}^{e} = {A}_{R} \cdot {V}_{R}^{- 1} \cdot {v}^{TA} , \qquad ( 88 )$$

where A_{R} is the matrix whose columns contain the VSH coefficients of the reference antennas, and V_{R} is the matrix whose columns represent the probe measurements from the corresponding calibration antenna. This can be interpreted as a weighted sum of the VSH coefficients from the reference antennas, with weights given by

$$w = {V}_{R}^{- 1} \cdot {v}^{TA} . \qquad ( 89 )$$

In practice, the matrix V_{R} may be poorly conditioned, in which case a preferred approach would be to choose Nₚ>>N_{Λ}, and then perform a least-square fit to find the weights of the reference antenna measurement vectors that best approximates the measurement vector for the AUT. In this case, the weights wᵢ that give the best approximation are obtained by minimizing

ε=(v^{TA}−v^{e})^{†}·v^{TA}−v^{e}. (90)
subject to the normalizing constraint

w^{T}·w=1. (91)

Here v^{e} is an estimate of the voltage vector created from a weighted sum of voltage vectors from the reference antennas:

v^{e}=V_{R}·W. (92)

Owing to the linearity of the system, once the weights w are obtained from the least-square fit, an estimate of the VSH coefficient vector can be obtained from

a^{e}=A_{R}·w. (93)

Once a^{e} is obtained from either method, an estimate of the antenna radiation resistance in free space Rᵣ is given by

$${R}_{r} = \frac{{\vert {a}^{e} \vert}^{2}}{{\vert {I}_{0} \vert}^{2} {η}_{0} {k}^{2}} , \qquad ( 94 )$$

where I₀ is the current at the antenna terminals in free space, η₀ is the impedance of free space, and k=2π/λ is the wavenumber in free space.

We now turn our attention to the calculation of the elements of the voltage matrix V_{R} in a rectangular waveguide.

### III. WAVEGUIDE MODE EXPANSION

At distances large enough to neglect evanescent mode coupling between the dipole and sampling probes, the total electric field can be expressed as a sum over propagating modes:

$$E = {\sum }_{u = 1}^{N} {E}_{u} = {\sum }_{u = 1}^{N} {C}_{u} {\vec{ε}}_{u} ( r ) . \qquad ( 95 )$$

Here each of the N propagating modes is associated with a “path,” Eᵤ is the electric field of mode u, Cᵤ is the amplitude of mode u, and \vec{εᵤ} is the normalized electric field of mode u as given in Appendix A. For thin wire antennas, the mode amplitudes are given by [5]-[7],

$${C}_{u} = - \frac{{I}_{0}}{4 {p}_{u}} \int \vec{{ε}_{u}} ( ξ ) \cdot \hat{ξ} \frac{sin k ( l - ξ )}{sin kl} d ξ ≡ - \frac{{F}_{u}}{4 {p}_{u}} {I}_{0} , \qquad ( 96 )$$

where ξ is the coordinate along the antenna, k is the wave number in free space, and pᵤ is the normalized mode power given in Appendix A.

After traveling a distance d, the mode amplitudes become

$${\tilde{C}}_{u} ( d ) = {C}_{u} {e}^{- j {β}_{u} d} ≡ {\hat{C}}_{u} {e}^{- j {β}_{u} d} {I}_{0} , \qquad ( 97 )$$

$${\hat{C}}_{u} = - \frac{{F}_{u}}{4 {p}_{u}} \qquad ( 98 )$$

By reciprocity, this mode then induces a current in the receiving probe antenna given by

$${I}_{u} = - \frac{4 {p}_{u}}{{F}_{u}^{( R )}} {\tilde{C}}_{u} ( d ) = - \frac{4 {p}_{u} {e}^{- j {β}_{u} d}}{{F}_{u}^{( R )}} \text{?} {I}_{0} , \qquad ( 99 )$$

where the superscript (R) refers to the receive antenna. The quantity Fᵤ^{(R)} is calculated for the structure of the receive antenna, but located at z=0 (the phase shift from position is taken care of by (97)). This current induces a voltage in the receiving antenna given by

$${V}_{u} = {I}_{u} {Z}_{u}^{( R )} = - {Z}_{u}^{( R )} \frac{4 {p}_{u} {e}^{- j {β}_{u} d}}{{F}_{u}^{( R )}} {\hat{C}}_{u} {I}_{0} , \qquad ( 100 )$$

where Zᵤ^{(R)} is the contribution to the receive antenna impedance from mode u. If a load impedance Z_{L} is placed across the terminals of the receiving antenna, the total voltage delivered to the load from all of the modes will be

$${V}_{L} = \frac{{Z}_{L}}{{Z}_{L} + {Z}_{a}^{( R )}} {\sum }_{u = 1}^{N} {V}_{u} . \qquad ( 101 )$$

If the load impedance is Z_{L}=Z₀, the voltage delivered by the receive antenna to the load will be

$${V}_{L} = \frac{{I}_{0} {Z}_{0}}{{Z}_{0} + {Z}_{a}^{( R )}} {\sum }_{u = 1}^{N} {Z}_{u}^{( R )} \frac{{F}_{u}^{( T )}}{{F}_{u}^{( R )}} {e}^{- j {β}_{u} d} . \qquad ( 102 )$$

The elements of the calibration voltage matrix V representing the voltage at the pth probe antenna from the qth reference antenna can be written

$${V}_{p , q} = \frac{{I}_{0} {Z}_{0}}{{Z}_{0} + {Z}_{a}^{( p )}} {\sum }_{u = 1}^{N} {Z}_{u}^{( p )} \frac{{F}_{u}^{( q )}}{{F}_{u}^{( p )}} {e}^{- j {β}_{u} d} , \qquad ( 103 )$$

where 1≤q≤N_{A} 1≤p≤NΛ. This can also be expressed in terms of S parameters (more convenient for measurements):

$${S}_{p , q} = \frac{1}{2 {Z}_{0}} ( 1 - {S}_{p p} ) ( 1 - {S}_{p p} ) {\sum }_{u = 1}^{N} {Z}_{u}^{( p )} \frac{{F}_{u}^{( q )}}{{F}_{u}^{( p )}} {e}^{- j {β}_{u} d} . \qquad ( 104 )$$

If we design the antenna probe to be at resonance, then Zₐ=Rₐ. If we further neglect ohmic and dielectric losses in the antenna, the real part of the impedance is given by

$${R}_{a} = {\sum }_{u = 1}^{N} {R}_{u} , \qquad ( 105 )$$

$$where [ 6 ]$$

$${R}_{u} = \frac{{\vert {F}_{u} \vert}^{2}}{4 {p}_{u}} \qquad ( 106 )$$

Note that Rₐ here is the actual radiation resistance in the waveguide, and is not the same as the radiation resistance Rr of the antenna in free space given by (94). Explicit expressions for the coupling integrals Fᵤ for x-oriented probes, y-oriented probes, and an arbitrarily positioned and oriented half-wavelength dipole are given in Appendix B.

### IV. NUMERICAL EXAMPLES

Similar to the cases discussed in the theory and experiments sections above, we consider both the reference antennas and the antenna under test to be half-wave dipoles as a simple example.

As discussed in the theory section above, 10 spherical harmonics are sufficient for a detailed representation of an electric dipole, and a reasonable approximation can be obtained with 3 harmonics. Keeping in mind modeling with both 3 and 10 terms, in this work we first use 10 calibration antenna orientations and 10 probe locations. FIGS. 4A and 4B provide a set of 10 calibration antenna orientations that does a reasonable job of illuminating the 10 spherical harmonic coefficients needed to represent an electric dipole. These orientations are listed in Table VII for convenience.

TABLE VII: Orientations of half-wave dipoles used for calibration.

| θ (rad) | φ (rad) |
|---|---|
| 0.0030 | 3.1423 |
| 1.6198 | 0.0021 |
| 1.7206 | 0.6835 |
| 0.8041 | −0.007 |
| 1.3731 | 1.6019 |
| 2.3203 | 0.4366 |
| 0.8800 | 1.1552 |
| 0.7304 | 2.3465 |
| 0.9266 | 4.8522 |
| 1.2949 | 5.5179 |

TABLE VIII
Seed values for antenna and probe positions indicated in Table IX.

| Parameter | Distribution |
|---|---|
| x₀, x₁, x₃, x₅, x₇, x₉ | Uniform, (0.1a, 0.9a) |
| y₀, y₂, y₄, y₆, y₈, y₁0 | Uniform, (0.1b, 0.9b) |
| z₁, z₂, z₃, . . . z₁0 | Uniform, (0.25, 1) m |

For the numerical example, a=0.3556 m (14 in) and b=0.3048 m (12 in).

Our channel model applies to a single dipole test antenna and a single receiving probe. If the receiving probe is strongly coupled to the modes, the mode content will be changed for subsequent probes. To minimize coupling and this source of model error, probes of length λ/16 were used in the calculations.

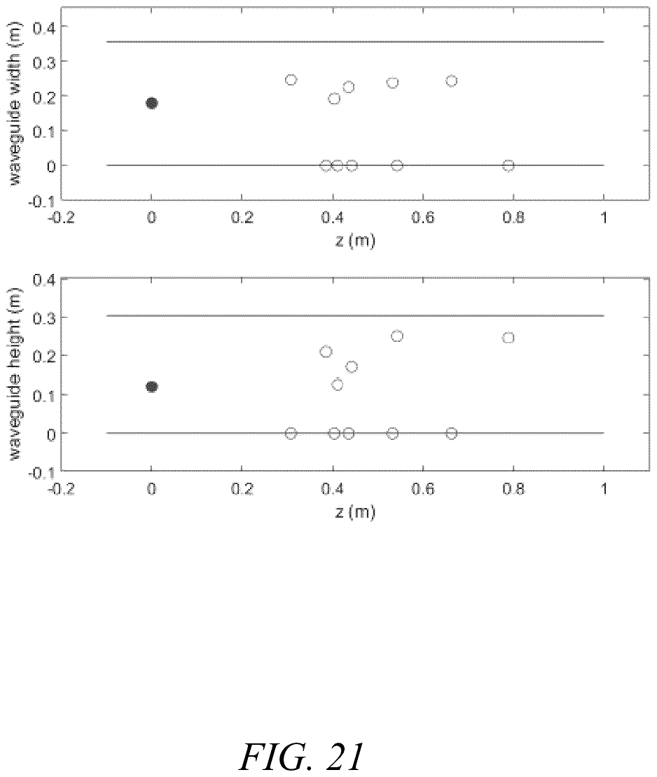

To find optimum waveguide probe antenna locations, we first generated 100 random seed locations along the width and height of the waveguide, with distributions as described in Table VIII. The seed locations with the lowest value of condo were selected as the seed for optimization. The final values of the 22 variables (6 values of x, 6 values of y, and 10 values of z) were then obtained using the MATLAB® function fminsearch to minimize the values of cond( ). The final values are given in Table IX and illustrated in FIG. 21. The result of the optimization gave cond( )=62.75. While still considerably larger than the ideal value of unity, this value nevertheless enables reasonably accurate numerical matrix inversion in our example.

Alternatively, the negative of the 1-entropy could be minimized instead of cond(V̅), as these quantities are correlated. However, cond(V̅) was used in the present analysis as it is more directly related to the actual calculation required for the matrix inversion approach.

TABLE IX
Positions of Antenna Under Test and waveguide
probe antennas for a = 0.3556 m (14 in),
b = 0.3048 m (12 in), and f = 3 GHz.

| Index i | xᵢ | yᵢ | zᵢ |
|---|---|---|---|
| 0 (AUT) | 0.1803 | 0.1222 | 0 |
| 1 | 0.1927 | 0 | 0.4029 |
| 2 | 0 | 0.1708 | 0.4425 |
| 3 | 0.2477 | 0 | 0.3075 |
| 4 | 0 | 0.1277 | 0.4100 |
| 5 | 0.2255 | 0 | 0.4358 |
| 6 | 0 | 0.2090 | 0.3853 |
| 7 | 0.2392 | 0 | 0.5325 |
| 8 | 0 | 0.2514 | 0.5424 |
| 9 | 0.1445 | 0 | 0.6634 |
| 10 | 0 | 0.2468 | 0.7881 |

Our channel model also neglects coupling from evanescent modes. For the dimensions chosen (a=0.3556 m (14 in) and b=0.3048 m (12 in)), there are 46 propagating modes at f=3 GHz. The cutoff of the next highest TE and TM modes is f=3.1125 GHz. At 3 GHz, these evanescent modes decay with a 1/e distance of 0.0576 m. This corresponds to an attenuation of about 46.4 dB at the shortest probe distance in in Table IX (z=0.3075 m).

Similar to the experiment section above, the case for representing the dipole with only 3 VSH coefficients was also explored. In this case the calibration orientations were along the three coordinate axes, and a least-squares fit using probe voltages was used to find the coefficients of each calibration antenna.

As in the experiment section above, the RMS error in the coefficient weights is used as a metric for the quality of the pattern analysis:

Δw_{RMS}=(w^{e}−w₀)^{T}·(w^{e}−w₀)/N, (107)

RMSE(dB)=20 log₁₀(Δw_{RMS}) (108)

Here N=10 for the matrix inversion method, and N=3 for the least-squares method. For the matrix inversion method the reference weight vector w₀ is obtained from

$${w}_{0} = {A}_{R}^{- 1} \cdot a . \qquad ( 109 )$$

where a is the VSH coefficient vector calculated directly from theoretical fields of a dipole at orientation (θ₀, φ₀). For the least-squares method with only three reference antennas, the correct weight vector is

w₀=[cos θ₀,sin θ₀ cos φ₀,sin θ₀ sin φ₀]^{T} (110)

As previously mentioned, the dipole impedance will be different inside the waveguide and will vary with position and orientation. In a typical experimental implementation this would result in different currents for the different orientations. To normalize to a uniform current in all antennas, each column of A_{R} and V_{R} would need to be multiplied by the correction factor

$$\frac{{I}_{a}}{{I}_{0}} = \frac{2 {Z}_{0}}{{R}_{a} + {Z}_{0}} . \qquad ( 111 )$$

However, this correction factor will cancel in the construction

$${A}_{R} \cdot {V}_{R}^{- 1}$$

so this correction can be omitted in the matrix inversion analysis.

On the other hand, this correction is required for Eqn. (92) to be valid, and so is required for the least-squares analysis.

Once the least-square estimates for the weights w are obtained, Eqn. (93) can be used to obtain an estimate of the corresponding VSH vector without any corrections to the matrix A_{R}.

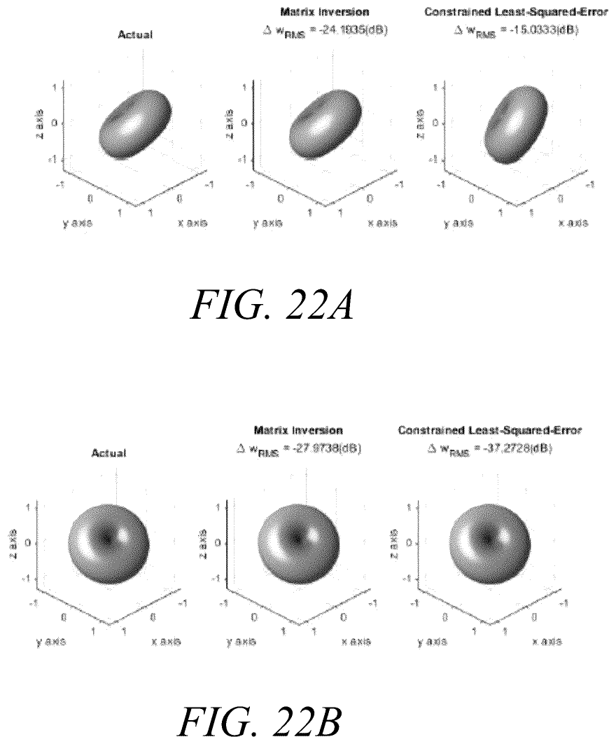

Example calculations for a variety of angles are summarized in Table X. The orientations chosen are the same as used in the theory section. Although the average RMSE is comparable for the Matrix Inverse and Constrained LSE, there is more variation in the RMSE for the constrained LSE. Generally speaking, when the RMSE is less than about −22 dB, the pattern and orientation are difficult to distinguish visually from the “Actual” case, so the Matrix Inverse method gives consistently acceptable results. In contrast, there are several orientations that give RMSE greater than −22 dB for the Constrained LSE case. Pattern examples for one of the worse cases as well as one of the better cases are shown in FIGS. 22A and 22B.

Since random noise is not introduced in the calculations, the numerical error associated with the Matrix-Inverse method is probably due to the relatively large condition numbers on A and V. On the other hand, the cause of the accuracy variations in the Constrained LSE method is less clear. In particular, the orientations of the representative worst and best cases shown in FIGS. 22A and 22B only differ by the sign of φ.

### V. CONCLUSION

Numerical modeling of the use of multimode propagation in a rectangular waveguide to construct antenna patterns has been presented. Analysis using both a Matrix Inverse method and a Constrained Least Squared Error demonstrates the feasibility of the approach. The advantages of using multimode waveguide propagation instead of multipath propagation in an open environment include a controlled and fixed geometry that can be optimized for the target application, insensitivity to movement or changes in the room environment, and relatively small size. However, variations in the accuracy of the Constrained Least Squared Error approach suggests that the example geometry can be further optimized.

### APPENDIX A

### Rectangular Waveguide Modes [7]

### For TE Modes:

$${ε}_{x} = \frac{j k}{{g}_{n , m}^{2}} \frac{m π}{b} cos \frac{n π x}{a} sin \frac{m π y}{b} {e}^{- j {β}_{n , {m}^{z}}} \qquad ( 112 )$$

$${ε}_{y} = \frac{j k}{{g}_{n , m}^{2}} \frac{n π}{a} sin \frac{n π x}{a} cos \frac{m π y}{b} {e}^{- j {β}_{n , {m}^{z}}} \qquad ( 113 )$$

### For TM Modes:

$${ε}_{x} = \frac{j {β}_{n , m}}{{g}_{n , m}^{2}} \frac{n π}{a} cos \frac{n π x}{a} sin \frac{m π y}{b} {e}^{- j {β}_{n , {m}^{z}}} \qquad ( 114 )$$

$${ε}_{y} = \frac{j {β}_{n , m}}{{g}_{n , m}^{2}} \frac{m π}{b} sin \frac{n π x}{a} cos \frac{m π y}{b} {e}^{- j {β}_{n , {m}^{z}}} \qquad ( 115 )$$

$${ε}_{z} = sin \frac{n π x}{a} sin \frac{m π y}{b} {e}^{- j {β}_{n , {m}^{z}}} \qquad ( 116 )$$

$$where$$

$${β}_{n , m} = \sqrt{{k}^{2} - {g}_{n , {m}^{′}}^{2}} \qquad ( 117 )$$

$${g}_{n , m} = \sqrt{{( n π / a )}^{2} + {( m π / b )}^{2}} \qquad ( 118 )$$

The normalized mode power is given by

$${p}_{n , m} = \frac{k {β}_{n , m} a b}{2 {X}_{n} {X}_{m} {g}_{n , m}^{2} η} , \qquad ( 119 )$$

$$where$$

$${x}_{q} = \{ \begin{matrix}1 & q = 0 \\ 2 & q > 0\end{matrix} . \qquad ( 120 )$$

In the above, k=ω/c=2Tπf/c where c is the speed of light in free space. Note that we have used a slightly different normalization for the TE modes than [7]. The normalization used here allows for the use of a single expression 32 to be used for both TE and TM modes.

TABLE X
Summary of example results. The fact that all of the Rᵣ values for the
Constrained LSE analysis are identical is a consequence of the imposed
constraint along with the orthogonality of the VSH coefficient vectors.

| | θ | φ | Rₐ | Matrix Inverse | | Constrained LSE | |
|---|---|---|---|---|---|---|---|
| Orientation # | (deg) | (deg) | Ω | RMSE (dB) | Rᵣ (Ω) | RMSE (dB) | Rᵣ (Ω) |
| 1 | 18 | 0 | 179.2 | −24.78 | 73.58 | −19.50 | 72.90 |
| 2 | 18 | 120 | 181.8 | −24.85 | 73.15 | −25.69 | 72.90 |
| 3 | 18 | −120 | 181.1 | −24.09 | 72.87 | −20.01 | 72.90 |
| 4 | 42 | 60 | 136.4 | −27.97 | 73.39 | −37.27 | 72.90 |
| 5 | 42 | 180 | 129.9 | −27.91 | 73.05 | −27.90 | 72.90 |
| 6 | 42 | −60 | 136.4 | −24.19 | 73.73 | −15.03 | 72.90 |
| 7 | 90 | 30 | 70.9 | −23.66 | 73.21 | −32.64 | 72.90 |
| 8 | 90 | 120 | 77.26 | −22.25 | 73.67 | −19.17 | 72.90 |
| 9 | 90 | 210 | 70.85 | −23.66 | 73.21 | −32.42 | 72.90 |
| 10 | 90 | −60 | 77.26 | −22.25 | 73.67 | −19.17 | 72.90 |
| mean values | | | | −24.56 | 73.35 | −24.88 | 72.90 |

### APPENDIX B

### Coupling Integrals

A. Coupling Integrals for y-Oriented Probe

For a y-oriented probe located in the z=0 plane and mounted on the y=0 surface, the coupling integral is given by

$${F}_{u}^{( y )} = {\int }_{0}^{l} \vec{ε} ( {x}_{1} , y , 0 ) \cdot \hat{y} \frac{sin k ( l - y )}{sin kl} dy . \qquad ( 121 )$$

Using the mode fields given in Appendix A, we have for TE modes:

$${F}_{n , m}^{( TE , y )} = - \frac{j k}{{g}_{n , m}^{2}} \frac{n π}{a} \frac{sin ( n π {x}_{1} / a )}{sin kl} \times {\int }_{0}^{l} cos ( m π y / b ) sin k ( l - y ) dy = - \frac{j}{{g}_{n , m}^{2}} \frac{n π}{a} \frac{sin ( n π {x}_{1} / a )}{sin kl} \times [ \frac{cos ( m π l / b ) - cos kl}{1 - {( m π / ( kb ) )}^{2}} ] . \qquad ( 122 )$$

For TM modes the result is

$${F}_{n , m}^{( T M , y )} == - \frac{j}{{g}_{n , m}^{2}} \frac{{β}_{n , m}}{k} \frac{m π}{b} \frac{sin ( n π {x}_{1} / a )}{sin kl} \times [ \frac{cos ( m π l / b ) - cos kl}{1 - {( m π / ( kb ) )}^{2}} ] . \qquad ( 123 )$$

B. Coupling Integrals for x-Oriented Probe

Similarly, the coupling integral for an x-oriented probe located in the z=0 plane and mounted on the x=0 surface is given by

$${F}_{u}^{( x )} = {\int }_{0}^{l} \vec{ε} ( x , {y}_{2} , 0 ) \cdot \hat{x} \frac{sin k ( l - x )}{sin kl} dx . \qquad ( 124 )$$

Again using the mode fields in Appendix A, we have for TE modes:

$${F}_{n , m}^{( TE , , x )} = \frac{j}{{g}_{n , m}^{2}} \frac{m π}{b} \frac{sin ( m π {y}_{2} / b )}{sin kl} \times [ \frac{cos ( n π l / a ) - cos kl}{1 - {( n π / ( ka ) )}^{2}} ] , \qquad ( 125 )$$

and for TM modes:

$${F}_{n , m}^{( T M x )} = - \frac{j}{{g}_{n , m}^{2}} \frac{{β}_{n , m}}{k} \frac{n π}{a} \frac{sin ( m π {y}_{2} / b )}{sin kl} \times [ \frac{cos ( n π l / a ) - cos kl}{1 - {( n π / ( ka ) )}^{2}} ] . \qquad ( 126 )$$

### C. Coupling Integral for an Arbitrarily Oriented Dipole

Consider an arbitrarily-oriented dipole inside the waveguide, with center at (x₀, y₀) in the z=0 plane. The coupling integral takes the form

$${F}_{u}^{( d )} = {\int }_{0}^{l} \vec{ε} ( {r}_{+} ) \cdot \hat{r} \frac{sin k ( l - r )}{k l} dr + {\int }_{0}^{l} \vec{ε} ( {r}_{-} ) \cdot \hat{r} \frac{sin k ( l - r )}{k l} dr , \qquad ( 127 )$$

$$where$$

$${r}_{+} = [ {x}_{0} + r sin {θ}_{0} cos {ϕ}_{0} , {y}_{0} + r sin {θ}_{0} sin {ϕ}_{0} , r cos {θ}_{0} ] , \qquad ( 128 )$$

$$And$$

$${r}_{-} = [ {x}_{0} - r sin {θ}_{0} cos {ϕ}_{0} , {y}_{0} - r sin {θ}_{0} sin {ϕ}_{0} - r cos {θ}_{0} ] . \qquad ( 129 )$$

The unit vector in the direction of the dipole axis is given by

\hat{r}=\hat{x} sin θ₀ cos φ₀+ŷ sin θ₀ sin φ₀+\hat{z} cos θ₀. (130)

These integrals can be evaluated numerically for both TE and TM modes using the mode field expressions given in Appendix A.

The disclosure of each of the following references is incorporated herein by reference in its entirety.

### REFERENCES

[1]T. Sarkar and O. Pereira, “Using the matrix pencil method to estimate the parameters of a sum of complex exponentials,” IEEE Antennas and Propagation Magazine, vol. 37, no. 1, pp. 48-55, 1995. [Online]. Available: https://ieeexplore.ieee.org/abstract/document/370583
[2]B. Fourestie, Z. Altman, and M. Kanda, “Anechoic chamber evaluation using the matrix pencil method,” IEEE Transactions on Electromagnetic Compatibility, vol. 41, no. 3, pp. 169-174, August. 1999. [Online]. Available: https://ieeexplore.ieee.org/abstract/document/784150?
[3]S. Loredo, M. Pino, F. Las-Heras, and T. Sarkar, “Echo identification and cancellation techniques for antenna measurement in non-anechoic test sites,” IEEE Antennas and Propagation Magazine, vol. 46, no. 1, pp. 100-107, February 2004. [Online]. Available: https://ieeexplore.ieee.org/abstract/document/1296154
[4]G. Leon Fernandez, S. Loredo, S. Zapatero, and F. Las-Heras, “RADIATION PATTERN RETRIEVAL IN NON-ANECHOIC CHAMBERS USING THE MATRIX PENCIL ALGORITHM,” Progress In Electromagnetics Research Letters, vol. 9, pp. 119-127, 2009. [Online]. Available: http://www.jpier.org/PIERL/pier.php?paper=09051204
[5]H.-J. Li, T.-Y. Liu, and J.-L. Leou, “Antenna Measurements in the Presence of Multipath Waves,” Progress In Electromagnetics Research, vol. 30, pp. 157-178, 2001. [Online]. Available: http://www.jpier.org/PIER/pier.php?paper=0002091
[6]S. Loredo, G. Leon, S. Zapatero, and F. Las-Heras, “Measurement of Low-Gain Antennas in Non-Anechoic Test Sites through Wideband Channel Characterization and Echo Cancellation [Measurements Corner],” IEEE Antennas and Propagation Magazine, vol. 51, no. 1, pp. 128-135, February 2009. [Online]. Available: https://ieeexplore.ieee.org/abstract/document/4939035?
[7]Z. Du, J. I. Moon, S.-s. Oh, J. Koh, and T. K. Sarkar, “Generation of Free Space Radiation Patterns From Non-Anechoic Measurements Using Chebyshev Polynomials,” IEEE Transactions on Antennas and Propagation, vol. 58, no. 8, pp. 2785-2790, August 2010. [Online]. Available: https://ieeexplore.ieee.org/abstract/document/5471170?
[8]A. Soltane, G. Andrieu, E. Perrin, C. Decroze, and A. Reineix, “Antenna Radiation Pattern Measurement in a Reverberating Enclosure Using the Time-Gating Technique,” IEEE Antennas and Wireless Propagation Letters, vol. 19, no. 1, pp. 183-187, January 2020. [Online]. Available: https://ieeexplore.ieee.org/abstract/document/8920101?
[9]J. Olencki, V. Waladi, A. Bekasiewicz, and L. Leifsson, “A Low-Cost System for Far-Field Non-Anechoic Measurements of Antenna Performance Figures,” IEEE Access, vol. 11, pp. 39 165-39 175, 2023. [Online]. Available: https://ieeexplore.ieee.org/abstract/document/10103864
[10]D. Black and E. Joy, “Test zone field compensation,” IEEE Transactions on Antennas and Propagation, vol. 43, no. 4, pp. 362-368, April 1995. [Online]. Available: https://ieeexplore.ieee.org/abstract/document/376033?
[11]D. Leatherwood and E. Joy, “Plane wave, pattern subtraction, range compensation,” IEEE Transactions on Antennas and Propagation, vol. 49, no. 12, pp. 1843-1851, December 2001. [Online]. Available: https://ieeexplore.ieee.org/abstract/document/982468
[12]P. Leather and D. Parsons, “Equalization for antenna-pattern measurements: established technique—new application,” IEEE Antennas and Propagation Magazine, vol. 45, no. 2, pp. 154-161, April 2003. [Online]. Available: https://ieeexplore.ieee.org/abstract/document/1203134?
[13]V. Fiumara, A. Fusco, V. Matta, and I. Pinto, “Free-space antenna field/pattern retrieval in reverberation environments,” IEEE Antennas and Wireless Propagation Letters, vol. 4, pp. 329-332, 2005. [Online]. Available: https://ieeexplore.ieee.org/document/1512069
[14]A. Cozza and A. e.-B. A. el Aileh, “Accurate Radiation-Pattern Measurements in a Time-Reversal Electromagnetic Chamber,” IEEE Antennas and Propagation Magazine, vol. 52, no. 2, pp. 186-193, April 2010. [Online]. Available: https://ieeexplore.ieee.org/abstract/document/5525625?
[15]G. Ferrara, A. Gifuni, and A. Sorrentino, “Test on antennas in a Reverberating Chamber and comparison with anechoic chamber,” in 2012 6th European Conference on Antennas and Propagation (EUCAP), March 2012, pp. 2154-2157, iSSN: 2164-3342. [Online]. Available: https://ieeexplore.ieee.org/abstract/document/6206270
[16]V. Fiumara, A. Fusco, G. ladarola, V. Matta, and I. M. Pinto, “Free-Space Antenna Pattern Retrieval in Nonideal Reverberation Chambers,” IEEE Transactions on Electromagnetic Compatibility, vol. 58, no. 3, pp. 673-677, June 2016. [Online]. Available: https://ieeexplore.ieee.org/abstract/document/7437434
[17]A. K. Puls, J. M. Ladbury, and W. F. Young, “Antenna Radiation Pattern Measurements Using a Reverberation Chamber,” in 2018 AMTA Proceedings, November 2018, pp. 1-6, iSSN: 2474-2740. [Online]. Available: https://ieeexplore.ieee.org/abstract/document/8604182?
[18]A. Reis, F. Sarrazin, P. Besnier, P. Pouliguen, and E. Richalot, “Contactless Antenna Gain Pattern Estimation From Backscattering Coefficient Measurement Performed Within a Reverberation Chamber,” IEEE Transactions on Antennas and Propagation, vol. 70, no. 3, pp. 2318-2321, March 2022. [Online]. Available: https://ieeexplore.ieee.org/abstract/document/9538833?
[19]A. Sorrentino, G. Ferrara, A. Gifuni, and M. Migliaccio, “Antenna pattern in a multipath environment emulated in a reverberating chamber,” in 2013 7th European Conference on Antennas and Propagation (EuCAP), April 2013, pp. 3561-3565. [Online]. Available: https://ieeexplore.ieee.org/abstract/document/6546973
[20]C. Lemoine, E. Amador, P. Besnier, J.-M. Floc'h, and A. Laisne, “Antenna Directivity Measurement in Reverberation Chamber From Rician K-Factor Estimation,” IEEE Transactions on Antennas and Propagation, vol. 61, no. 10, pp. 5307-5310, October 2013. [Online]. Available: https://ieeexplore.ieee.org/abstract/document/6557073?
[21]P. Besnier, C. Lemoine, J. Sol, and J.-M. Floch, “Radiation pattern measurements in reverberation chamber based on estimation of coherent and diffuse electromagnetic fields,” in 2014 IEEE Conference on Antenna Measurements & Applications (CAMA), November 2014, pp. 1-4. [Online]. Available: https://ieeexplore.ieee.org/abstract/document/7003323?
[22]M. Garcia-Fernandez, D. Carsenat, and C. Decroze, “Antenna Radiation Pattern Measurements in Reverberation Chamber Using Plane Wave Decomposition,” IEEE Transactions on Antennas and Propagation, vol. 61, no. 10, pp. 5000-5007, October 2013. [Online]. Available: https://ieeexplore.ieee.org/abstract/document/6553351
[23]______, “Antenna Gain and Radiation Pattern Measurements in Reverberation Chamber Using Doppler Effect,” IEEE Transactions on Antennas and Propagation, vol. 62, no. 10, pp. 5389-5394, October 2014. [Online]. Available: https://ieeexplore.ieee.org/abstract/document/6863647?
[24] Foschini and M. Gans, “On Limits of Wireless Communications in a Fading Environment when Using Multiple Antennas,” Wireless Personal Communications, vol. 6, no. 3, pp. 311-335, March 1998.[Online]. Available: https://doi.org/10.1023/A:1008889222784
[25]E. Telatar, “Capacity of Multi-antenna Gaussian Channels,” European Transactions on Telecommunications, vol. 10, no. 6, pp. 585-595, 1999, eprint: https://onlinelibrary.wiley.com/doi/pdf/10.1002/ett.4460100604. [On-line]. Available: https://onlinelibrary.wiley.com/doi/abs/10.1002/ett.4460100604
[26]E. L. Hill, “The Theory of Vector Spherical Harmonics,” American Journal of Physics, vol. 22, no. 4, pp. 211-214, April 1954. [Online]. Available: https://aapt.scitation.org/doi/abs/10.1119/1.1933682
[27]R. H. Lambert, “Complete vector spherical harmonic expansion for Maxwells equations,” Am. J. Phys., vol. 46, no. 8, p. 849, 1978.
[28]B. C. Brock, “Using Vector Spherical Harmonics to Compute Antenna Mutual Impedance from Measured or Computed Fields,” Tech. Rep. SAND2000-2217, 763320, September 2000. [Online]. Available: http://www.osti.gov/servlets/purl/763320-IdDDPB/webviewable/
[29]R. Allard and D. Werner, “The model-based parameter estimation of antenna radiation patterns using windowed interpolation and spherical harmonics,” IEEE Transactions on Antennas and Propagation, vol. 51, no. 8, pp. 1891-1906, August 2003. [Online]. Available: https://ieeexplore.ieee.org/abstract/document/1219598?
[30]L. R. Ximenes and A. L. F. de Almeida, “Capacity Evaluation of MIMO Antenna Systems Using Spherical Harmonics Expansion,” in 2010 IEEE 72nd Vehicular Technology Conference—Fall, September 2010, pp. 1-5, iSSN: 1090-3038. [Online]. Available: https://ieeexplore.ieee.org/abstract/document/5594365
[31]L. Marantis, E. De Witte, and P. V. Brennan, “Comparison of various spherical antenna array element distributions,” in 2009 3rd European Conference on Antennas and Propagation, March 2009, pp. 2980-2984, iSSN: 2164-3342. [Online]. Available: https://ieeexplore.ieee.org/abstract/document/5068232?
[32]J. Rahola, F. Belloni, and A. Richter, “Modelling of radiation patterns using scalar spherical harmonics with vector coefficients,” Proc. 3rd European Conf. on Ant. & Prop. (EuCAP 2009), pp. 3361-3365, 2009.
[33]Z. Mhanna, A. Sibille, M. A. Yousuf, and C. Roblin, “Parametric statistical modeling of power gain patterns for RFID backscattering channels,” in 2012 6th European Conference on Antennas and Propagation (EUCAP), March 2012, pp. 1041-1045, iSSN: 2164-3342. [Online]. Available: https://ieeexplore.ieee.org/abstract/document/6206277?
[34]A. Schmitz, T. Karolski, and L. Kobbelt, “Using spherical harmonics for modeling antenna patterns,” in 2012 IEEE Radio and Wireless Symposium, January 2012, pp. 155-158, iSSN: 2164-2974. [Online]. Available: https://ieeexplore.ieee.org/abstract/document/6175298?
[35]M. Mhedhbi, S. Avrillon, and B. Uguen, “Comparison of vector and Scalar Spherical Harmonics expansions of UWB antenna patterns,” in 2013 International Conference on Electromagnetics in Advanced Applications (ICEAA), September 2013, pp. 1040-1043. [Online]. Available: https://ieeexplore.ieee.org/abstract/document/6632401?
[36]B. Fuchs, L. Le Coq, S. Rondineau, and M. D. Migliore, “Fast Antenna Far-Field Characterization via Sparse Spherical Harmonic Expansion,” IEEE Transactions on Antennas and Propagation, vol. 65, no. 10, pp. 5503-5510, October 2017. [Online]. Available: https://ieeexplore.ieee.org/abstract/document/8007310?
[37]B. Fuchs, L. L. Coq, S. Rondineau, and M. D. Migliore, “Compressive Sensing Approach for Fast Antenna Far Field Characterization,” September 2018, pp. 278 (5 pp.)-278 (5 pp.), publisher: IET Digital Library. [Online]. Available: https://digital-library.theiet.org/content/conferences/10.1049/cp.2018.0637
[38]N. Mezieres, B. Fuchs, L. L. Coq, J.-M. Lerat, R. Contreres, and G. L. Fur, “On the Application of Sparse Spherical Harmonic Expansion for Fast Antenna Far-Field Measurements,” IEEE Antennas and Wireless Propagation Letters, vol. 19, no. 5, pp. 746-750, May 2020. [Online]. Available: https://ieeexplore.ieee.org/abstract/document/9023941?
[39] Mezieres, B. Fuchs, L. Le Coq, J.-M. Lerat, R. Contreres, and G. Le Fur, “Fast Antenna Characterization Improvement by Pattern Rotation,” IEEE Transactions on Antennas and Propagation, vol. 69, no. 5, pp. 2952-2957, May 2021. [Online]. Available: https://ieeexplore.ieee.org/abstract/document/9234653?
[40]______, “On the Antenna Positioning for a Faster and Better Radiation Pattern Characterization,” in 2021 15th European Conference on Antennas and Propagation (EuCAP), March 2021, pp. 1-4. [Online]. Available: https://ieeexplore.ieee.org/abstract/document/9411316?
[41]Z. Huang, X. Li, J. Chen, and B. Chen, “Rapid Analysis of Conformal Antenna Arrays via Vector Spherical Harmonics Translation,” in 2022 IEEE MTT-S International Wireless Symposium (IWS), vol. 1, August 2022, pp. 1-3. [Online]. Available: https://ieeexplore.ieee.org/abstract/document/9977654
[42]J. D. Jackson, Classical Electrodynamics Third Edition, 3rd ed. New York: Wiley, August 1998.
[43]C. Cappellin, O. Breinbjerg, and A. Frandsen, “Properties of the transformation from the spherical wave expansion to the plane wave expansion,” Radio Science, vol. 43, no. 1, February 2008. [Online]. Available: https://agupubs.onlinelibrary.wiley.com/doi/abs/10.1029/2007RS003696
[44]F. Jensen and A. Frandsen, “On the number of modes in spherical wave expansions,” Proc. 26th AMTA, pp. 489-94, 2004.
[45]E. Candes and M. Wakin, “An Introduction To Compressive Sampling,” IEEE Signal Process. Mag., vol. 25, no. 2, pp. 21-30, 2008.
[46]H. R. Behjoo, A. Pirhadi, and R. Asvadi, “Optimal Sampling in Spherical Near-Field Antenna Measurements by Utilizing the Information Content of Spherical Wave Harmonics,” IEEE Transactions on Antennas and Propagation, vol. 70, no. 5, pp. 3762-3771, May 2022. [Online]. Available: https://ieeexplore.ieee.org/abstract/document/9664490?
[47]M. D. Migliore, “On Electromagnetics and Information Theory,” IEEE Transactions on Antennas and Propagation, vol. 56, no. 10, pp. 3188-3200, October 2008. [Online]. Available: https://ieeexplore.ieee.org/abstract/document/4636839?
[48]L. H. Hemming, Electromagnetic Anechoic Chambers. IEEE Press, Wiley-Interscience, 2002.
[49]Q. Xu and Y. Huang, Anechoic and Reverberation Chambers: Theory, Design, and Measurements. IEEE Press, Wiley-Interscience, 2019.
[50] Fourestie, Z. Altman, J. Wiart, and A. Azoulay, “Correlate measurements at different test sites,” IEEE Trans. Antennas Propag., vol. 47, no. 10, pp. 1569-1573, October 1999. [Online]. Available: https://ieeexplore.ieee.org/abstract/document/805901
[51] OpenAl, “Chatgpt: Language model,” Accessed: 2026-02-02, 2026. [Online]. Available: https://www.openai.com/chatgpt
[52]P. Nikitin, D. Stancil, A. Cepni, O. Tonguz, A. Xhafa, and D. Brodtkorb, “Propagation model for the HVAC duct as a communication channel,” IEEE Trans. Antennas Prop., vol. 51, no. 5, pp. 945-951, 2003.
[53]R. E. Collin, Foundations for Microwave Engineering, 2nd ed. McGraw-Hill, 1992.
[54]D. M. Pozar, Microwave Engineering, 4th ed. Wiley & Sons, Inc., December 2011.

It will be understood that various details of the subject matter described herein may be changed without departing from the scope of the subject matter described herein. Furthermore, the foregoing description is for the purpose of illustration only, and not for the purpose of limitation, as the subject matter described herein is defined by the claims as set forth hereinafter.

What is claimed is:

1. A method for multipath-enhanced measurement of antenna radiation patterns, the method comprising:
determining relationships between reference signals measured or generated by sensing antennas in a multipath environment and functions defined on a surface of a sphere;
applying a signal to the antenna under test located in the multipath environment;
detecting, by each of a plurality of sensing antennas, signals radiated by the antenna under test, including multipath reflections of radiated energy in the multipath environment; and
determining, using the detected signals and the relationships between the reference signals and the functions defined on the surface of the sphere, a radiation pattern of the antenna under test.

2. The method of claim 1 wherein determining relationships between reference signals measured or generated by sensing antennas in the multipath environment and functions defined on a surface of a sphere includes causing at least one reference antenna having a known radiation pattern to radiate in the multipath environment, detecting the reference signals at each of the sensing antennas, and determining a coupling between reference signals, the functions defined on the surface of the sphere, and propagation paths in the multipath environment.

3. The method of claim 2 wherein determining, using the detected signals and the relationships between the reference signals and the functions defined on the surface of the sphere, a radiation pattern of the antenna under test includes inverting the coupling and determining amplitudes of the functions defined on the surface of the sphere by multiplying amplitudes of the detected signals by the inverted coupling.

4. The method of claim 3 wherein inverting the coupling includes using a least squares error method.

5. The method of claim 3 wherein inverting the coupling includes using matrix inversion.

6. The method of claim 1 wherein determining relationships between reference signals measured or generated by sensing antennas in the multipath environment and functions defined on a surface of a sphere includes placing, in the multipath environment, at least one reference antenna having a known radiation pattern, causing each of the sensing antennas to radiate, detecting, by the at least one reference antenna, the reference signals generated as a result of the radiation of sensing antennas, and determining a coupling between the reference signals, the functions defined on the surface of the sphere, and propagation paths in the multipath environment.

7. The method of claim 1 wherein the functions defined on the surface of the sphere comprise vector spherical harmonics.

8. The method of claim 1 wherein placing the antenna under test in the multipath environment includes placing the antenna under test in a non-anechoic room.

9. The method of claim 1 wherein placing the antenna under test in the multipath environment includes placing the antenna under test in a waveguide.

10. The method of claim 1 wherein placing the antenna under test in the multipath environment includes placing the antenna under test in a reverberation chamber.

11. A system for multipath-enhanced measurement of antenna radiation patterns, the system comprising:
at least one processor;
a plurality of sensing antennas for sensing direct and multipath radiation from an antenna under test in a multipath environment;
an antenna radiation pattern determiner/test controller implemented by the at least one processor for determining relationships between reference signals measured or generated by the sensing antennas in the multipath environment and functions defined on a surface of a sphere;
a signal source for applying a signal to the antenna under test;
wherein each of the sensing antennas detect signals radiated by the antenna under test, including multipath reflections of radiated energy in the multipath environment; and
wherein the antenna radiation pattern determiner/test controller determines, using the detected signals and the relationships between the reference signals and the functions defined on the surface of the sphere, a radiation pattern of the antenna under test.

12. The system of claim 11 wherein determining relationships between reference signals measured or generated by sensing antennas in the multipath environment and functions defined on a surface of a sphere includes causing at least one reference antenna having a known radiation pattern to radiate in the multipath environment, detecting the reference signals at each of the sensing antennas, and determining a coupling between reference signals, the functions defined on the surface of the sphere, and propagation paths in the multipath environment.

13. The system of claim 12 wherein determining, using the detected signals and the relationships between the reference signals and the functions defined on the surface of the sphere, a radiation pattern of the antenna under test includes inverting the coupling and determining amplitudes of the functions defined on the surface of the sphere by multiplying amplitudes of the detected signals by the inverted coupling.

14. The system of claim 13 wherein inverting the coupling includes using a least squares error method.

15. The system of claim 13 wherein inverting the coupling includes using matrix inversion.

16. The system of claim 11 wherein determining relationships between reference signals measured or generated by sensing antennas in the multipath environment and functions defined on a surface of a sphere includes placing, in the multipath environment, at least one reference antenna having a known radiation pattern, causing each of the sensing antennas to radiate, detecting, by the at least one reference antenna, the reference signals generated as a result of the radiation of sensing antennas, and determining a coupling between the reference signals, the functions defined on the surface of the sphere, and propagation paths in the multipath environment.

17. The system of claim 11 wherein the functions defined on the surface of the sphere comprise vector spherical harmonics.

18. The system of claim 11 wherein the multipath environment includes a non-anechoic room.

19. The system of claim 11 wherein the multipath environment includes a waveguide.

20. The system of claim 11 wherein the multipath environment includes a reverberation chamber.

21. A non-transitory computer readable medium having stored thereon executable instructions that when executed by a processor of a computer control the computer to perform steps comprising:
determining relationships between reference signals measured by sensing antennas in a multipath environment and functions defined on a surface of a sphere;
applying a signal to an antenna under test located in the multipath environment;
detecting, by each of a plurality of sensing antennas, signals radiated by an antenna under test located in the multipath environment, including multipath reflections of radiated energy in the multipath environment; and
determining, using the detected signals and the relationships between the reference signals and the functions defined on the surface of the sphere, a radiation pattern of the antenna under test.

22. The non-transitory computer readable medium of claim 21 wherein the functions defined on the surface of the sphere comprise vector spherical harmonics.
